(19) United States
(12) Patent Application Publication
(10) Pub. No.: US 2016/0032163 A1
(43) Pub. Date: Feb. 4, 2016

(54) METHOD FOR FORMING COATING LAYER AND COATING MATERIAL HAVING WATERPROOF PROPERTY

(71) Applicants: Industry-Academic Cooperation Foundation, Yonsei University, Seoul (KR); Incheon University Industry Academic Cooperation Foundation, Incheon (KR)

(72) Inventors: Hyungjun Kim, Seoul (KR); Il-Kwon Oh, Seoul (KR); Han-Bo-Ram Lee, Seoul (KR)

(21) Appl. No.: 14/814,888

(22) Filed: Jul. 31, 2015

(30) Foreign Application Priority Data
Aug. 1, 2014 (KR) 10-2014-0098865

(51) Int. Cl. C09K 3/18; C23C 16/02; C08K 3/22

(52) U.S. Cl. CPC C09K 3/18; C08K 3/22; C23C 16/0227; C08K 2003/221

(57) ABSTRACT

The present disclosure relates to a method for forming a coating layer and a coating material having waterproof property, and the method for forming a coating layer according to the present disclosure includes (a) supplying a precursor comprising a rare earth metal onto a substrate; (b) purging impurities of remaining precursor after combination of the rare earth metal onto the substrate; (c) supplying an oxidant onto the substrate; and (d) purging remaining impurities after forming a coating layer including a rare earth oxide on the substrate. According to the method for forming a coating layer of the present disclosure, a coating layer with hydrophobic or superhydrophobic property may be formed by controlling a temperature of the substrate so that an atomic ratio of a carbon element in the coating layer is less than 1% to form the coating layer with hydrophobic or superhydrophobic property.

### TECHNICAL FIELD

The present disclosure herein relates to a method for forming a coating layer and a coating material having waterproof property.

This invention was derived from studies conducted as a part for developing fundamental technology of industrial fusion by the Ministry of knowledge economy (project number 2012-8-1046, development on high density plasma technique for depositing an inorganic thin film for processing an ultrafine semiconductor and a flexible display).

### BACKGROUND ART

The requirement on a hydrophobic coating material in many fields including automobile parts and products for cooking is increasing. Recently, a hydrophobic coating material using hydrocarbon receives spotlight. Hydrocarbon has merits of small surface energy and small friction-resistance and abrasion-resistance. However, at the temperature of 250° C. and more, dehydrogenation reaction is gradually generated in a hydrocarbon hydrophobic material, and the properties of the material are markedly deteriorated.

### DESCRIPTION OF THE INVENTION

### Technical Problem

The present disclosure provides a method for forming a coating layer with hydrophobic or superhydrophobic property by an atomic layer deposition method, and a coating material having waterproof property thereby.

The present disclosure also provides a method for forming a coating layer maintaining hydrophobic or superhydrophobic property after heat treatment at a high temperature, and a coating material with waterproof property maintaining hydrophobic or superhydrophobic property after heat treatment at a high temperature.

### Technical Solution

An embodiment of the inventive concept provides a method for forming a coating layer including (a) supplying a precursor including a rare earth metal onto a substrate; (b) purging impurities of remaining precursor after combination of the rare earth metal onto the substrate; (c) supplying an oxidant onto the substrate; and (d) purging remaining impurities after forming a coating layer including a rare earth oxide on the substrate, wherein a temperature of the substrate is controlled so that an atomic ratio of a carbon element in the coating layer is less than 1% to form a coating layer with hydrophobic or superhydrophobic property.

In an embodiment of the inventive concept, the rare earth metal may include yttrium.

In an embodiment of the inventive concept, the temperature of the substrate may be controlled to from 160 to 200° C. so that the atomic ratio of a carbon element in the coating layer may be less than 1% to form the coating layer with hydrophobic or superhydrophobic property.

In an embodiment of the inventive concept, the precursor may include Y(iPr(Cp)₂(N-iPr-amd).

In an embodiment of the inventive concept, the supplying of the precursor in the step of (a) may be conducted so that exposure time of the substrate to the precursor is greater than or equal to 1.5 seconds, and the supplying of the oxidant in the step of (c) may be conducted so that exposure time of the substrate to the oxidant is greater than or equal to 0.5 seconds.

In an embodiment of the inventive concept, the oxidant may include H₂O.

In an embodiment of the inventive concept, the rare earth metal oxide may include yttrium oxide (Y₂O₃).

In an embodiment of the inventive concept, the rare earth metal may include dysprosium.

In an embodiment of the inventive concept, the temperature of the substrate may be controlled to from 145 to 230° C. so that the atomic ratio of a carbon element in the coating layer may be less than 1% to form the coating layer with hydrophobic or superhydrophobic property.

In an embodiment of the inventive concept, the precursor may include Dy(iPrCp)₂(N-iPr-amd).

In an embodiment of the inventive concept, the supplying of the precursor in the step of (a) may be conducted so that exposure time of the substrate to the precursor may be greater than or equal to 2 seconds, and the supplying of the oxidant in the step of (c) may be conducted so that exposure time of the substrate to the oxidant is greater than or equal to 0.5 seconds.

In an embodiment of the inventive concept, the oxidant may include plasma O₂.

In an embodiment of the inventive concept, the rare earth metal oxide may include dysprosium oxide (Dy₂O₃).

In an embodiment of the inventive concept, the rare earth metal may include erbium.

In an embodiment of the inventive concept, the temperature of the substrate may be controlled to from 180 to 250° C. so that the atomic ratio of a carbon element in the coating layer may be less than 1% to form the coating layer with hydrophobic or superhydrophobic property.

In an embodiment of the inventive concept, the precursor may include Er(MeCp)₂(N-iPr-amd).

In an embodiment of the inventive concept, the supplying of the precursor in the step of (a) may be conducted so that exposure time of the substrate to the precursor is greater than or equal to 3 seconds, and the supplying of the oxidant in the step of (c) may be conducted so that exposure time of the substrate to the oxidant is greater than or equal to 1 second.

In an embodiment of the inventive concept, the oxidant may include H₂O.

In an embodiment of the inventive concept, the rare earth metal oxide may include erbium oxide (Er₂O₃).

In an embodiment of the inventive concept, the rare earth metal may include lanthanum.

In an embodiment of the inventive concept, the temperature of the substrate may be controlled to from 250 to 350° C. so that the atomic ratio of a carbon element in the coating layer may be less than 1% to form the coating layer with hydrophobic or superhydrophobic property.

In an embodiment of the inventive concept, the precursor may include La(iPrCp)₃.

In an embodiment of the inventive concept, the supplying of the precursor in the step of (a) may be conducted so that exposure time of the substrate to the precursor is greater than or equal to 3 seconds, and the supplying of the oxidant in the step of (c) may be conducted so that exposure time of the substrate to the oxidant is greater than or equal to 3 seconds.

In an embodiment of the inventive concept, the oxidant may include at least one selected from H₂O and plasma O₂.

In an embodiment of the inventive concept, the rare earth metal oxide may include lanthanum oxide (La₂O₃).

In an embodiment of the inventive concept, the rare earth metal may include cerium.

In an embodiment of the inventive concept, the temperature of the substrate may be controlled to from 200 to 300° C. so that the atomic ratio of a carbon element in the coating layer may be less than 1% to form the coating layer with hydrophobic or superhydrophobic property.

In an embodiment of the inventive concept, the precursor may include Ce(iPrCp)₃.

In an embodiment of the inventive concept, the supplying of the precursor in the step of (a) may be conducted so that exposure time of the substrate to the precursor is greater than or equal to 4 seconds, and the supplying of the oxidant in the step of (c) may be conducted so that exposure time of the substrate to the oxidant is greater than or equal to 3 seconds.

In an embodiment of the inventive concept, the oxidant may include plasma O₂.

In an embodiment of the inventive concept, the rare earth metal oxide may include cerium oxide (CeO₂).

In an embodiment of the inventive concept, the steps of (a) to (d) may be repeated to form the coating layer with hydrophobic or superhydrophobic property.

In an embodiment of the inventive concept, a coating material having waterproof property includes a substrate; and a coating layer including a rare earth metal oxide formed on the substrate by an atomic layer unit, wherein the coating layer has less than 1% of an atomic ratio of a carbon element to have hydrophobic or superhydrophobic property.

In an embodiment of the inventive concept, a contact angle of the coating layer with water may be greater than 90°.

In an embodiment of the inventive concept, the hydrophobic or superhydrophobic property of the coating layer may be maintained after heat treatment at 500° C. for 2 hours.

### Effects of the Invention

According to an embodiment of the inventive concept, a coating layer having hydrophobic or superhydrophobic property may be formed by an atomic layer deposition method.

In addition, according to an embodiment of the inventive concept, a coating layer maintaining hydrophobic or superhydrophobic property after heat treatment at a high temperature may be provided.

The effects of the inventive concept are not limited thereto. Unmentioned effects may be clearly understood by a person skilled in the art from the description and attached drawings.

### BRIEF DESCRIPTION OF DRAWINGS

FIG. 1 is a flowchart showing a method for forming a coating layer according to an embodiment of the inventive concept.

FIG. 2 is a graph showing a growth rate of an yttrium oxide coating layer relative to exposure time of a substrate to an yttrium precursor.

FIG. 3 is a graph showing a growth rate of an yttrium oxide coating layer relative to exposure time of a substrate to an oxidant.

FIG. 4 is a graph showing a growth rate of an yttrium oxide coating layer relative to the growth temperature (the temperature of a substrate) of a coating layer.

FIG. 5 is a graph showing a thickness of an yttrium oxide coating layer relative to cycle number.

FIG. 6 is a photographic image showing a state of dropping a droplet on an yttrium oxide coating layer formed on a substrate according to an embodiment of the inventive concept.

FIG. 7 is a graph obtained by measuring Y 3d binding energy of an yttrium oxide coating layer formed on a substrate according to an embodiment of the inventive concept.

FIG. 8 is a graph obtained by measuring O 1s binding energy of an yttrium oxide coating layer formed on a substrate according to an embodiment of the inventive concept.

FIG. 9 is a graph obtained by measuring C 1s binding energy of an yttrium oxide coating layer formed on a substrate according to an embodiment of the inventive concept.

FIG. 10 is a graph obtained by measuring N 1s, Y 3s binding energy of an yttrium oxide coating layer formed on a substrate according to an embodiment of the inventive concept.

FIG. 11 is a photographic image showing a state of dropping a droplet on an yttrium oxide coating layer formed on a substrate according to a comparative embodiment (the temperature of a substrate 300° C.).

FIG. 12 is a graph obtained by measuring Y 3d binding energy of an yttrium oxide coating layer formed on a substrate according to a comparative embodiment.

FIG. 13 is a graph obtained by measuring O 1s binding energy of an yttrium oxide coating layer formed on a substrate according to a comparative embodiment.

FIG. 14 is a graph obtained by measuring C 1s binding energy of an yttrium oxide coating layer formed on a substrate according to a comparative embodiment.

FIG. 15 is a photographic image showing a state of dropping a droplet after heat treatment at a high temperature on an yttrium oxide coating layer formed on a substrate according to an embodiment of the inventive concept.

FIG. 16 is a graph showing a growth rate of a dysprosium oxide coating layer relative to exposure time of a substrate to a dysprosium precursor.

FIG. 17 is a graph showing a growth rate of a dysprosium oxide coating layer relative to exposure time of a substrate to an oxidant.

FIG. 18 is a graph showing a growth rate of a dysprosium oxide coating layer relative to the growth temperature (the temperature of a substrate) of a coating layer.

FIG. 19 is a graph showing a thickness of a dysprosium oxide coating layer relative to cycle number.

FIG. 20 is a photographic image showing a state of a droplet dropped on a dysprosium oxide coating layer formed on a substrate according to an embodiment of the inventive concept.

FIG. 21 is a graph obtained by measuring Dy 4d binding energy of a dysprosium oxide coating layer formed on a substrate according to an embodiment of the inventive concept.

FIG. 22 is a graph obtained by measuring O 1s binding energy of a dysprosium oxide coating layer formed on a substrate according to an embodiment of the inventive concept.

FIG. 23 is a graph obtained by measuring N 1s binding energy of a dysprosium oxide coating layer formed on a substrate according to an embodiment of the inventive concept.

FIG. 24 is a graph obtained by measuring C 1s binding energy of a dysprosium oxide coating layer formed on a substrate according to an embodiment of the inventive concept.

FIG. 25 is a photographic image showing a state of a droplet dropped on a dysprosium oxide coating layer formed on a substrate after heat treatment at a high temperature according to an embodiment of the inventive concept.

FIG. 26 is a graph showing a growth rate of an erbium oxide coating layer relative to exposure time of a substrate to an erbium precursor.

FIG. 27 is a graph showing a growth rate of an erbium oxide coating layer relative to a growth temperature (the temperature of a substrate) of a coating layer.

FIG. 28 is a graph showing a thickness of an erbium oxide coating layer relative to cycle number.

FIG. 29 is a photographic image showing a state of a droplet dropped on an erbium oxide coating layer formed on a substrate according to an embodiment of the inventive concept.

FIG. 30 is a graph obtained by measuring Er 4d binding energy of an erbium oxide coating layer formed on a substrate according to an embodiment of the inventive concept.

FIG. 31 is a graph obtained by measuring O 1s binding energy of an erbium oxide coating layer formed on a substrate according to an embodiment of the inventive concept.

FIG. 32 is a graph obtained by measuring N 1s binding energy of an erbium oxide coating layer formed on a substrate according to an embodiment of the inventive concept.

FIG. 33 is a graph obtained by measuring C 1s binding energy of an erbium oxide coating layer formed on a substrate according to an embodiment of the inventive concept.

FIG. 34 is a photographic image showing a state of a droplet dropped on an erbium oxide coating layer formed on a substrate after heat treatment at a high temperature according to an embodiment of the inventive concept.

FIG. 35 is a graph showing a growth rate of a lanthanum oxide coating layer relative to exposure time of a substrate to a lanthanum precursor.

FIG. 36 is a graph showing a growth rate of a lanthanum oxide coating layer relative to the growth temperature (the temperature of a substrate) of a coating layer.

FIG. 37 is a photographic image showing a state of a droplet dropped on a lanthanum oxide coating layer formed on a substrate according to an embodiment of the inventive concept.

FIG. 38 is a graph obtained by measuring La 3d binding energy of a lanthanum oxide coating layer formed on a substrate according to an embodiment of the inventive concept.

FIG. 39 is a graph obtained by measuring O 1s binding energy of a lanthanum oxide coating layer formed on a substrate according to an embodiment of the inventive concept.

FIG. 40 is a graph showing a growth rate of a cerium oxide coating layer relative to exposure time of a substrate to a cerium precursor.

FIG. 41 is a graph showing a growth rate of a cerium oxide coating layer relative to the growth temperature (the temperature of a substrate) of a coating layer.

FIG. 42 is a photographic image showing a state of a droplet dropped on a cerium oxide coating layer formed on a substrate according to an embodiment of the inventive concept.

FIG. 43 is a graph obtained by measuring Ce 3d binding energy of a cerium oxide coating layer formed on a substrate according to an embodiment of the inventive concept.

FIG. 44 is a graph obtained by measuring O 1s binding energy of a cerium oxide coating layer formed on a substrate according to an embodiment of the inventive concept.

FIG. 45 is a graph obtained by measuring C 1s binding energy of a cerium oxide coating layer formed on a substrate according to an embodiment of the inventive concept.

FIG. 46 is a graph showing a contact angle of a coating layer formed on a substrate according to an embodiment of the inventive concept according to the kind of a rare earth oxide.

FIG. 47 is a cross-sectional view schematically showing a coating material having waterproof property according to an embodiment of the inventive concept.

FIG. 48 is a cross-sectional view schematically showing a coating material having waterproof property according to another embodiment of the inventive concept.

### DETAILED DESCRIPTION FOR CARRYING OUT THE INVENTION

The advantages and the features of the inventive concept, and methods for attaining them will be described in example embodiments below with reference to the accompanying drawings. The inventive concept may, however, be embodied in different forms and should not be construed as limited to the embodiments set forth herein. Rather, the inventive concept may be defined by the scope of claims. It will be further understood that terms (including technical or scientific terms) should be interpreted as having a meaning that is consistent with their meaning in the context of the relevant art.

In the drawings, like reference numerals refer to like elements throughout so far as possible. General explanation on known elements may be omitted so as not to obscure the gist of the inventive concept. It will also be understood that when a material is referred to as being ‘formed on ˜’ another material, it can be directly on the other material, or intervening materials may also be present.

In the method for forming a coating layer according to an embodiment of the inventive concept, the growing temperature (the temperature of a substrate) of a rare earth metal oxide is controlled so that the atomic ratio of a carbon element in the coating layer is less than 1% during forming a rare earth metal oxide coating layer on a substrate by an atomic layer deposition method to form a coating layer having hydrophobic or superhydrophobic property. That is, by controlling the temperature of the substrate so that the atomic ratio of a carbon element in the coating layer may be less than 1%, the coating layer formed by the atomic layer deposition method may have the hydrophobic or superhydrophobic property.

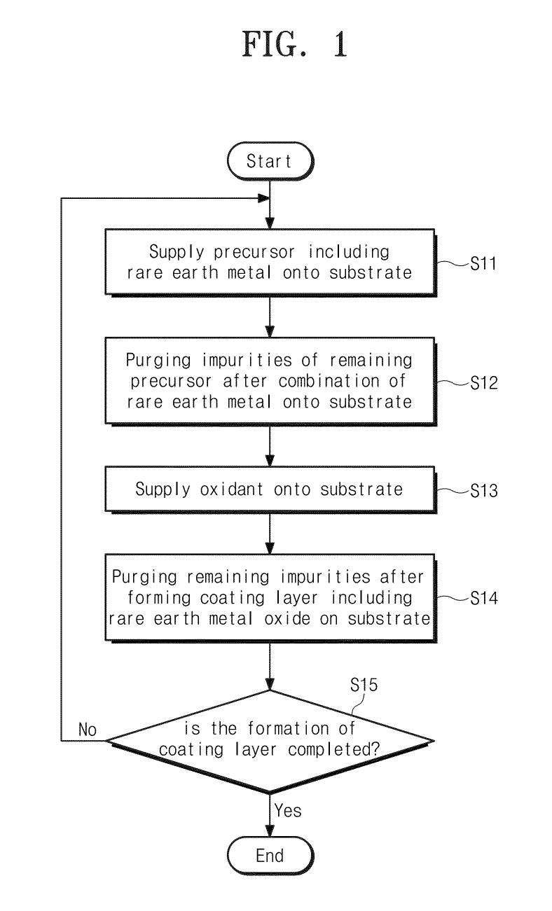

FIG. 1 is a flowchart showing a method for forming a coating layer according to an embodiment of the inventive concept. Referring to FIG. 1, the method for forming a coating layer according to an embodiment of the inventive concept includes a step of supplying a precursor including a rare earth metal onto the substrate (S11), a step of purging impurities of remaining precursor after the combination of the rare earth metal onto the substrate (S12), a step of supplying an oxidant onto the substrate (S13), and a step of purging remaining impurities after forming the coating layer including the rare earth metal oxide on the substrate (S14). The impurity may include impurity elements such as carbon and nitrogen. In order to form the coating layer having hydrophobic or superhydrophobic property, the temperature of the substrate is controlled in steps S11 to S14 so that the atomic ratio of a carbon element in the coating layer is less than 1%.

Exemplary embodiments of the inventive concept will be explained in more detail. First, a substrate is introduced in a reaction chamber of an atomic layer deposition apparatus. In order to form a coating layer having hydrophobic or superhydrophobic property, the temperature of the substrate may be controlled in advance so that the atomic ratio of a carbon element in the coating layer to be formed on the substrate is less than 1%. The temperature of the substrate for forming the coating layer having hydrophobic or superhydrophobic property may be changed according to a precursor including a rare earth metal oxide, which will be explained later. For example, the temperature of the substrate may be controlled by using a heater or other means for heating the substrate. The method for controlling the temperature of the substrate is not specifically limited, and various heating methods including conduction, convection, and radiation may be conducted.

Referring to FIG. 1 again, a precursor including a rare earth metal is supplied into a reaction chamber (S11). In an embodiment of the inventive concept, the precursor supplied onto the substrate may include at least one rare earth metal of yttrium (Y), dysprosium (Dy), erbium (Er), lanthanum (La) or cerium (Ce). The precursor may include, for example, at least one of Y(iPrCp)₂(N-iPr-amd), Dy(iPrCp)₂(N-iPr-amd), Er(MeCp)₂(N-iPr-amd), La(iPrCp)₃, or Ce(iPrCp)₃.

After exposing the substrate to the precursor for a predetermined time period in the step of S11, impurities of remaining precursor after the combination of the rare earth metal onto the substrate is purged (S12). In this case, the impurities of the precursor may include, for example, isopropylcyclopentadienyl (iPrCp), N-isopropyl-acetamidinate (N-iPr-amd), or methylcyclopentadienyl (MeCp) forming the precursor, or impurity elements separated therefrom such as carbon and nitrogen.

After purging the impurities for a predetermined time period in the step of S12, an oxidant is supplied onto the substrate (S13). The oxidant may include at least one of H₂O or plasma O₂. In an embodiment of the inventive concept, in the case of using an yttrium precursor or an erbium precursor as the precursor, an H₂O oxidant may be used. In the case of using a precursor including dysprosium or cerium, a plasma O₂ oxidant may be used. In the case of using a precursor including lanthanum, the H₂O or plasma O₂ oxidant may be used.

After exposing the substrate to the oxidant for a predetermined time period in the step of S13, remaining impurities after forming the coating layer including the rare earth metal oxide on the substrate is purged for a predetermined time period (S14). The purged impurities may include impurity elements, for example, isopropylcyclopentadienyl (iPrCp), N-isopropyl-acetamidinate (N-iPr-amd), or methylcyclopentadienyl (MeCp) forming the precursor, carbon, nitrogen, oxidant or hydrogen separated from the oxidant.

One cycle of the forming process of the coating layer via the steps of S11 to S14 is performed. The steps of S11 to S14 may be repeated for a predetermined number of times. That is, if further formation of the coating layer by an atomic layer unit is judged to be necessary in the step of S15, the process of the steps of S11 to S14 may be repeatedly conducted, and the coating layer including the rare earth metal oxide (for example, Y₂O₃, Dy₂O₃, La₂O₃, CeO₂ or Er₂O₃) may be formed on the substrate via conducting the forming process of the coating layer for several tens cycles.

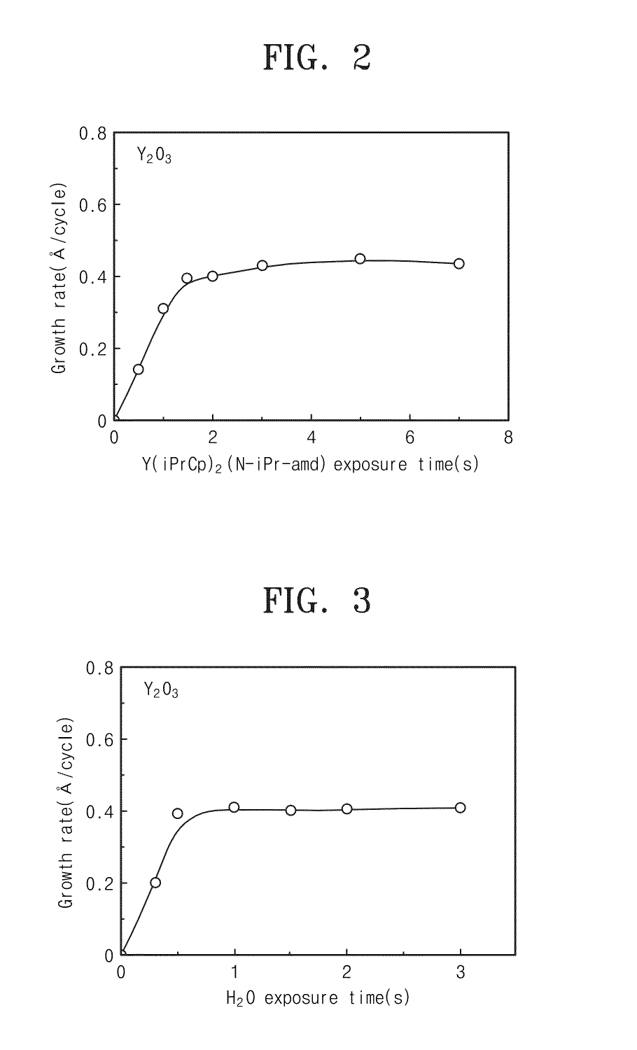

FIG. 2 is a graph showing a growth rate of an yttrium oxide coating layer relative to exposure time of a substrate to an yttrium precursor. An Si substrate was exposed to a Y(iPrCp)₂(N-iPr-amd) precursor in the step of S11, the substrate was exposed to an H₂O oxidant for 1 second to form an yttrium metal oxide coating layer in the step of S13, and the purging time periods of the steps of S12 and S14 were set to 5 seconds, respectively. The temperature of the substrate was maintained to 180° C., and the temperature of bubbling of the precursor and the oxidant was set to 130° C.

As shown in FIG. 2, if the exposure time to the precursor is greater than or equal to 1.5 seconds, the growth rate of the yttrium metal oxide coating layer per cycle is maintained to an appropriate level (about 0.4 Å/cycle). To secure the growth rate of the coating layer to a certain level, while decreasing processing time, the exposure time to the yttrium precursor may preferably be from 1.5 to 2 seconds.

FIG. 3 is a graph showing a growth rate of an yttrium oxide coating layer relative to exposure time of a substrate to an oxidant. The exposure time to the yttrium precursor was set to 2 seconds, and other experimental conditions were the same as those of FIG. 2. As shown in FIG. 3, if the exposure time to the oxidant is greater than or equal to 0.5 seconds, the growth rate of the yttrium metal oxide coating layer per cycle is maintained to an appropriate level (about 0.4 Å/cycle). To secure the growth rate of the coating layer to a certain level, while decreasing processing time, the exposure time to the oxidant may preferably be from 0.5 seconds to 1 second.

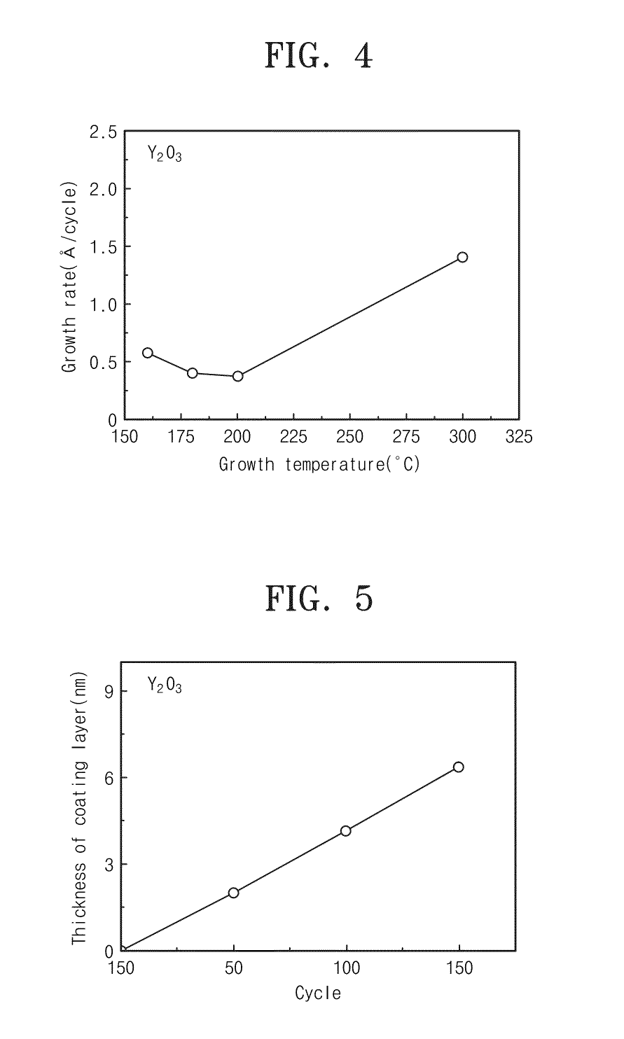

FIG. 4 is a graph showing a growth rate of an yttrium oxide coating layer relative to the growth temperature (the temperature of a substrate) of a coating layer. The supply time (exposure time) of the precursor was set to 2 seconds, and the exposure time to the oxidant was set to 1 second. Other experimental conditions were the same as those of FIG. 2. As shown in FIG. 4, if the yttrium precursor is used, and the temperature of the substrate is in a range of 160 to 200° C., the growth rate of the coating layer was secured to an appropriate level.

In the case of setting the temperature of the substrate to the temperature (300° C.) greater than 200° C., the growth rate of the yttrium oxide coating layer increases excessively. This is due to the inclusion of impurities other than yttrium oxide in the coating layer. That is, if the temperature of the substrate is greater than 200° C., the atomic ratio of a carbon element in the elements constituting the coating layer increases to greater than or equal to 1%, and the coating layer thus formed may not have hydrophobic or superhydrophobic property.

More preferable temperature of the substrate for forming the yttrium oxide coating layer is from 180 to 200° C. In the case of maintaining the temperature of the substrate at 160° C., the yttrium oxide coating layer may also have hydrophobic property, however the growth rate of the coating layer may be somewhat higher when compared to the case of maintaining the temperature of the substrate at 180° C. That is, the atomic ratio of a carbon element in the coating layer is increased to the proximate level of 1%. In the case of setting the temperature of the substrate to a temperature lower than 160° C., the atomic ratio of a carbon element in the coating layer may be greater than 1%, and hydrophobic or superhydrophobic property may not be obtained.

FIG. 5 is a graph showing a thickness of an yttrium oxide coating layer relative to cycle number. In this case, the temperature of the substrate was maintained to 180° C., and the exposure time of the precursor was set to 2 seconds. The thickness of the yttrium oxide coating layer was measured after 50, 100 and 150 cycles, and the remaining experimental conditions were the same as those of FIG. 2. Referring to FIG. 5, the thickness of the yttrium oxide coating layer increased in proportion to the cycle number. Thus, the coating layer with a desired thickness may be formed by controlling the cycle number in the forming process of the coating layer including the steps of S11 to S14 of FIG. 1, and the thickness of the coating layer may be controlled by the unit of less than 0.1 nm.

### Example 1

An experiment for securing the formation of a hydrophobic or superhydrophobic coating layer by a method for forming a coating layer according to an embodiment of the inventive concept was conducted. A cycle of exposing an Si substrate in a reaction chamber to a Y(iPrCp)₂(N-iPr-amd) precursor for 2 seconds, purging impurities for 5 seconds, exposing the substrate to an H₂O oxidant for 0.5 seconds and purging impurities for 5 seconds again, was conducted for several times to form an yttrium metal oxide coating layer with a thickness of 50 nm. The bubbling temperature of the precursor and the oxidant was set to 130° C. The temperature of the substrate was set to 180° C. in an embodiment of the inventive concept and was set to 300° C. according to a comparative embodiment.

The contact angles of the coating layers formed by an embodiment of the inventive concept and a comparative embodiment were measured to secure the realization of hydrophobic or superhydrophobic property. The contact angle is a value obtained by measuring an angle between the surface of the droplet in the droplet and the surface of the coating layer. If the contact angle increases, in simple language, as the droplet is not spread and has a spherical shape, the coating layer is evaluated to have hydrophobic or superhydrophobic property. In this disclosure, a hydrophobic coating layer is defined as a coating layer having a contact angle of greater than or equal to 90°, and a superhydrophobic coating layer is defined as a coating layer having a contact angle of greater than or equal to 150°.

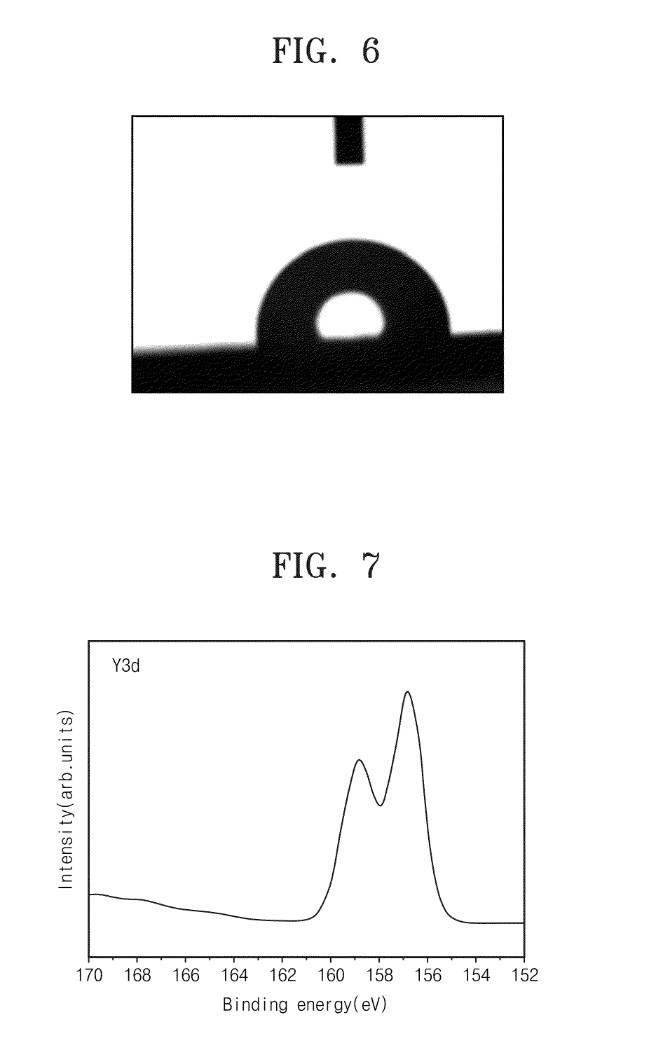

FIG. 6 is a photographic image showing a state of dropping a droplet on an yttrium oxide coating layer formed on a substrate according to an embodiment of the inventive concept. The contact angle of the droplet with respect to the yttrium oxide coating layer formed according to an embodiment of the inventive concept was 102°, and this result means that the yttrium oxide coating layer formed according to an embodiment of the inventive concept has hydrophobic property.

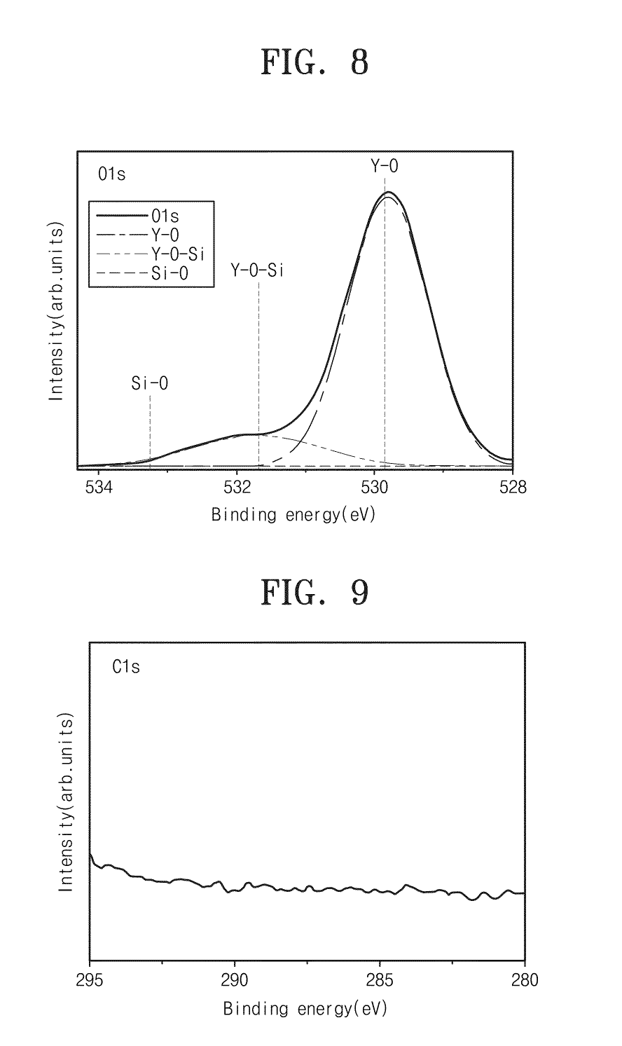

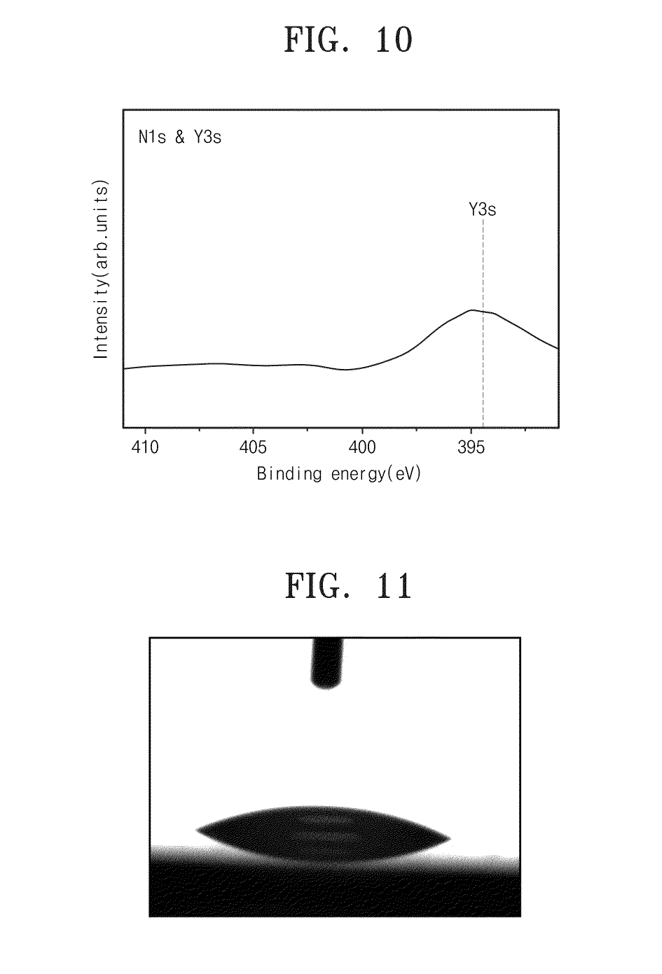

FIG. 7 is a graph obtained by measuring Y 3d binding energy of an yttrium oxide coating layer formed on a substrate according to an embodiment of the inventive concept, FIG. 8 is a graph obtained by measuring O 1s binding energy of an yttrium oxide coating layer formed on a substrate according to an embodiment of the inventive concept, FIG. 9 is a graph obtained by measuring C 1s binding energy of an yttrium oxide coating layer formed on a substrate according to an embodiment of the inventive concept, and FIG. 10 is a graph obtained by measuring N 1s, Y 3s binding energy of an yttrium oxide coating layer formed on a substrate according to an embodiment of the inventive concept.

The high peak intensity of the binding energy means the high ratio of a specific element showing the binding energy forming the peak, and the low peak intensity means the opposite. Accordingly, through the binding energy distribution, the atomic ratio of elements may be estimated. Referring to FIGS. 7 to 10, the peaks of C 1s, N 1s binding energy are rarely shown relative to the peaks of Y 3d, O 1s binding energy. By integrating and analyzing the distribution of the binding energy, the atomic ratio of a carbon element among elements constituting the coating layer was measured to be less than 1%, and the coating layer formed on the substrate according to an embodiment of the inventive concept exhibited hydrophobic property.

FIG. 11 is a photographic image showing a state of dropping a droplet on an yttrium oxide coating layer formed on a substrate according to a comparative example (the temperature of a substrate 300° C.). The yttrium oxide coating layer formed according to the comparative example did not exhibit hydrophobic property.

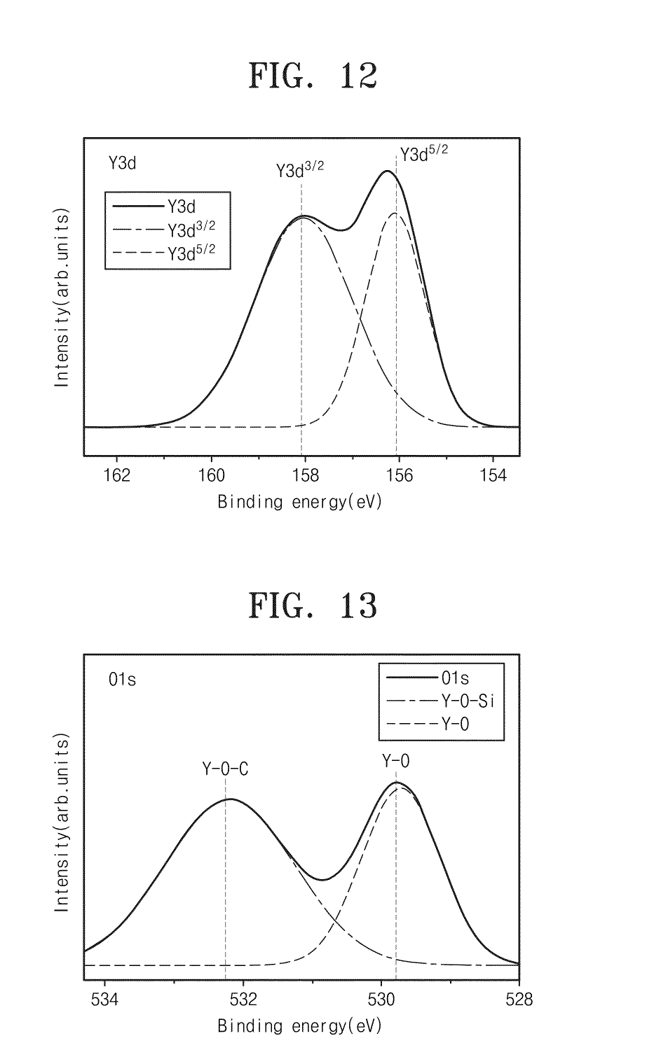

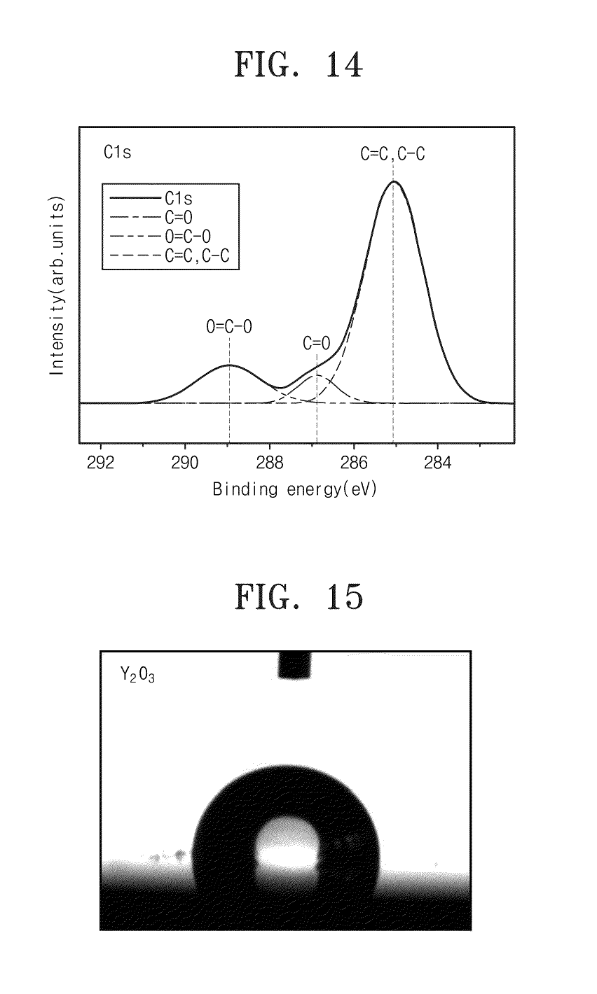

FIG. 12 is a graph obtained by measuring Y 3d binding energy of an yttrium oxide coating layer formed on a substrate according to a comparative example, FIG. 13 is a graph obtained by measuring O 1s binding energy of an yttrium oxide coating layer formed on a substrate according to a comparative example, and FIG. 14 is a graph obtained by measuring C 1s binding energy of an yttrium oxide coating layer formed on a substrate according to a comparative example.

Referring to FIGS. 12 to 14, relatively high peaks are shown in Y—O—C, O═C—O, C═O, C═C, C—C binding energy. By integrating and analyzing the distribution of the binding energy, the atomic ratio of Y:O:C was 27.8:38.6:33.7, and the atomic ratio of O/Y was 1.39. Thus, the atomic ratio of a carbon element was very high as not an Y₂O₃ coating layer but a YOC level, and thus, the coating layer formed on the substrate according to the comparative example did not have hydrophobic property.

To evaluate the stability at a high temperature of the yttrium oxide coating layer formed on the substrate according to an embodiment of the inventive concept, the yttrium oxide coating layer formed on the substrate was heat treated at 500° C. for 2 hours, and the contact angle of the coating layer was measured to evaluate hydrophobic property. FIG. 15 is a photographic image showing a state of dropping a droplet after heat treatment at a high temperature on an yttrium oxide coating layer formed on a substrate according to an embodiment of the inventive concept. The contact angle of the coating layer and the droplet after heat treatment was 110°, and the contact angle was increased from that (102°) before the heat treatment. It means that the coating layer manufactured according to an embodiment of the inventive concept maintained the hydrophobic property after heat treatment at a high temperature for a long time, and the hydrophobic property were rather increased when compared to that before the heat treatment.

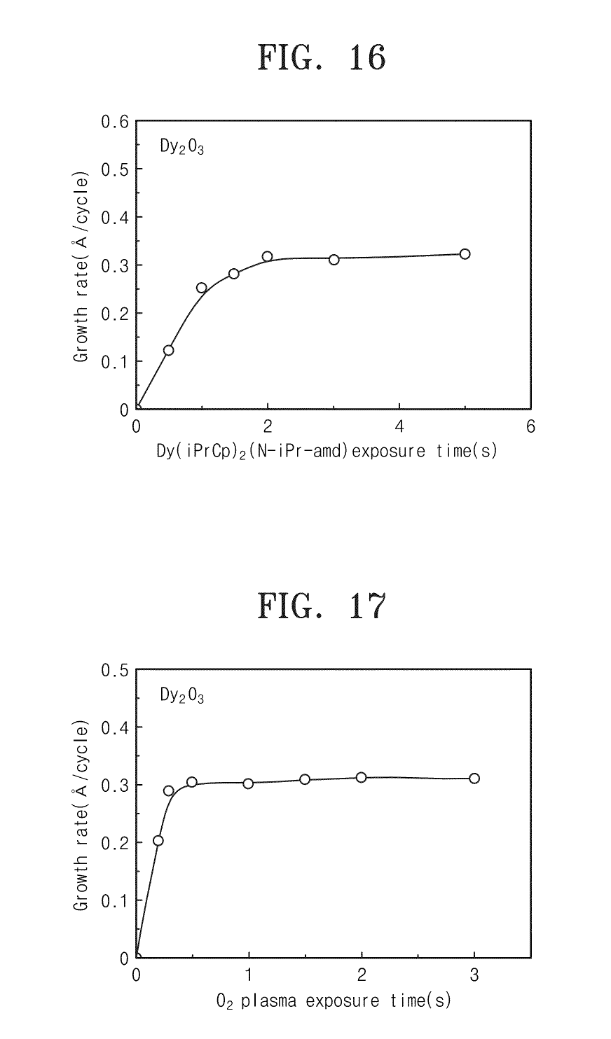

FIG. 16 is a graph showing a growth rate of a dysprosium oxide coating layer relative to exposure time of a substrate to a dysprosium precursor. A Si substrate was exposed to a Dy(iPrCp)₂(N-iPr-amd) precursor, impurities were purged for 5 seconds, the substrate was exposed to a plasma O₂ oxidant for 1 second and impurities were purged for 5 seconds again to form a dysprosium metal oxide coating layer. The temperature of the substrate was maintained at 180° C., and the bubbling temperature of the precursor and the oxidant was set to 120° C.

As shown in FIG. 16, if the exposure time to the precursor is greater than or equal to 2 seconds, the growth rate of the dysprosium metal oxide coating layer is maintained to an appropriate level (about 0.3 Å/cycle). In order to secure the growth rate of the coating layer to a certain level, while decreasing process time, the exposure time to the dysprosium precursor may preferably be from 2 to 3 seconds.

FIG. 17 is a graph showing a growth rate of a dysprosium oxide coating layer relative to exposure time of a substrate to an oxidant. The exposure time to the dysprosium precursor was set to 2 seconds, and other experimental conditions were set to the same experimental conditions of FIG. 16. As shown in FIG. 17, if the exposure time to the oxidant was greater than or equal to 0.5 seconds, the growth rate of the dysprosium metal oxide coating layer per cycle was maintained to an appropriate level (about 0.3 Å/cycle). In order to secure the growth rate of the coating layer to a certain level, while decreasing process time, the exposure time to the oxidant may preferably be from 0.5 to 1 second.

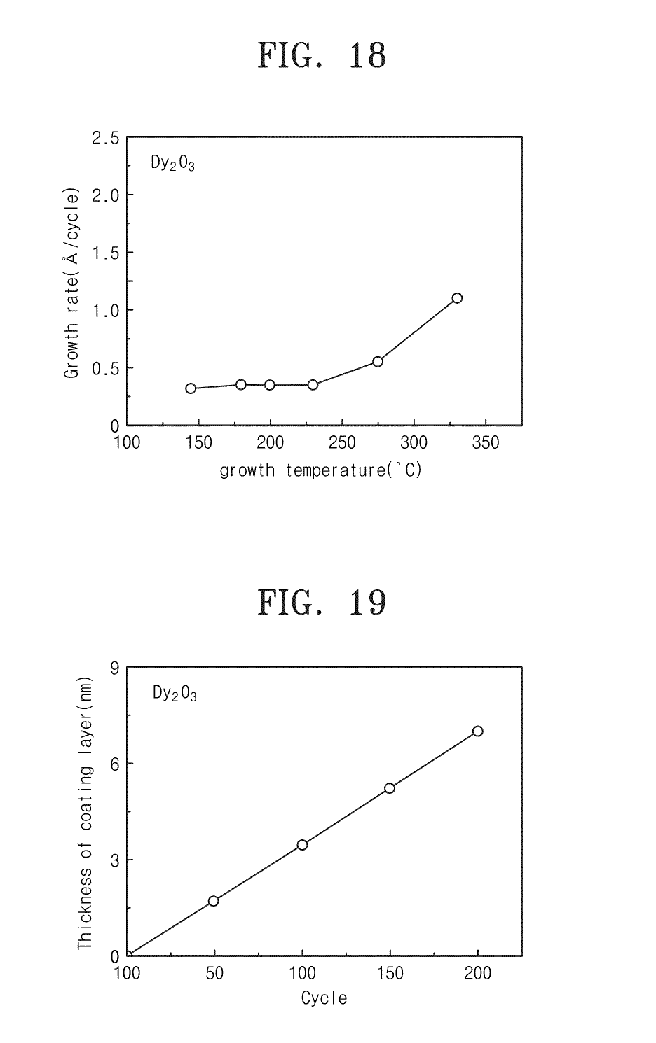

FIG. 18 is a graph showing a growth rate of a dysprosium oxide coating layer relative to the growth temperature (the temperature of a substrate) of a coating layer. The supply time (exposure time) of the precursor was set to 2 seconds, and the exposure time to the oxidant was set to 1 second. Other experimental conditions were set to the same experimental conditions of FIG. 16. As shown in FIG. 18, if the dysprosium precursor was used and the temperature of the substrate was in a range of 145 to 230° C., an appropriate level of the growth rate of the coating layer was secured.

If the temperature of the substrate is set to the temperatures (275° C., 325° C.) greater than 230° C., the growth rate of the dysprosium oxide coating layer increases. This result is obtained, because impurities other than the dysprosium oxide are included in the coating layer. That is, if the temperature of the substrate is greater than 230° C., the atomic ratio of a carbon element among elements constituting the coating layer may be greater than or equal to 1%, and the coating layer thus formed may not have hydrophobic or superhydrophobic property.

FIG. 19 is a graph showing a thickness of a dysprosium oxide coating layer relative to cycle number. The temperature of the substrate was maintained at 180° C., and the exposure time of the precursor was set to 2 seconds. The thickness of the dysprosium oxide coating layer was measured after performing 50, 100, 150 and 200 cycles, and the other experimental conditions were the same as those of FIG. 16. Referring to FIG. 19, the thickness of the dysprosium oxide coating layer was increased in proportion to the cycle number. Accordingly, a coating layer with a desired thickness may be formed by controlling the cycle number during the forming process of the coating layer including the steps of S11 to S14 of FIG. 1.

### Example 2

An experiment for securing the formation of a hydrophobic or superhydrophobic coating layer by the method for forming a coating layer according to an embodiment of the inventive concept was conducted. A cycle of exposing an Si substrate in a reaction chamber to a Dy(iPrCp)₂(N-iPr-amd) precursor for 2 seconds, purging impurities for 5 seconds, exposing the substrate to a plasma O₂ oxidant for 1 second and purging impurities for 5 seconds again, was conducted for several times to form a dysprosium metal oxide coating layer. The bubbling temperature of the precursor and the oxidant was set to 120° C., and the temperature of the substrate was set to 180° C. The contact angle of the dysprosium metal oxide coating layer formed according to an embodiment of the inventive concept was measured, and the realization of hydrophobic or superhydrophobic property was judged.

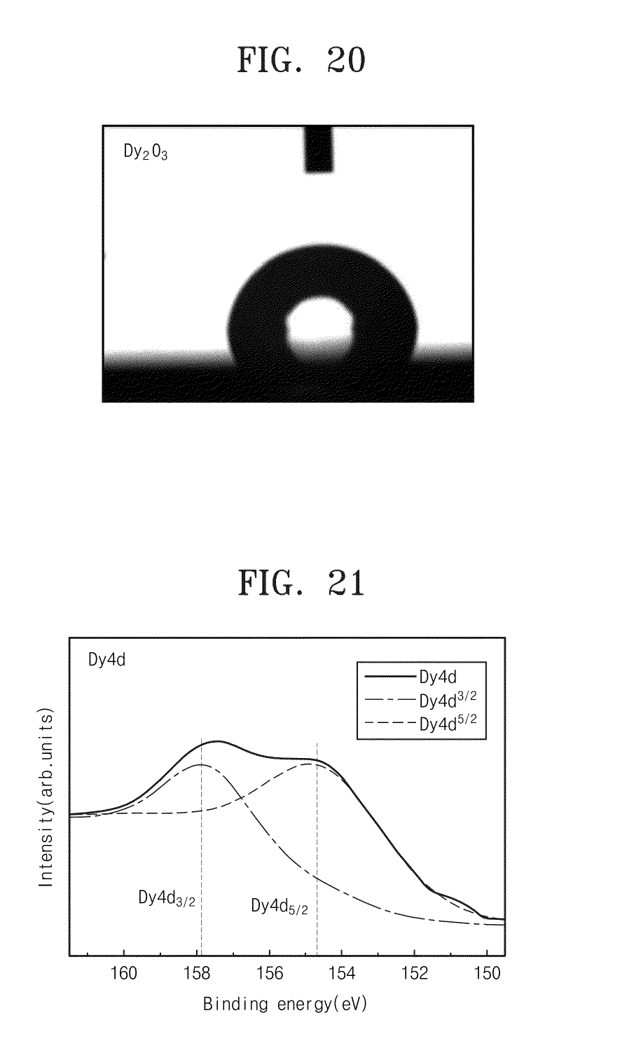

FIG. 20 is a photographic image showing a state of a droplet dropped on a dysprosium oxide coating layer formed on a substrate according to an embodiment of the inventive concept. The contact angle of the droplet with respect to the dysprosium oxide coating layer formed according to an embodiment of the inventive concept was 108°, and this result means that the dysprosium oxide coating layer formed according to an embodiment of the inventive concept has hydrophobic property.

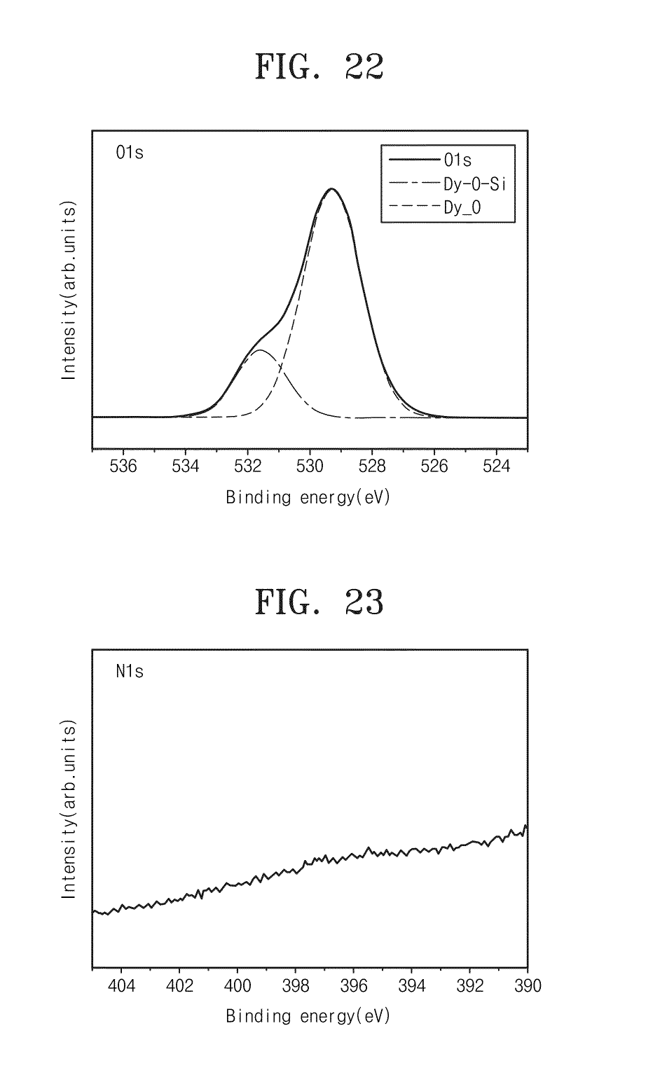

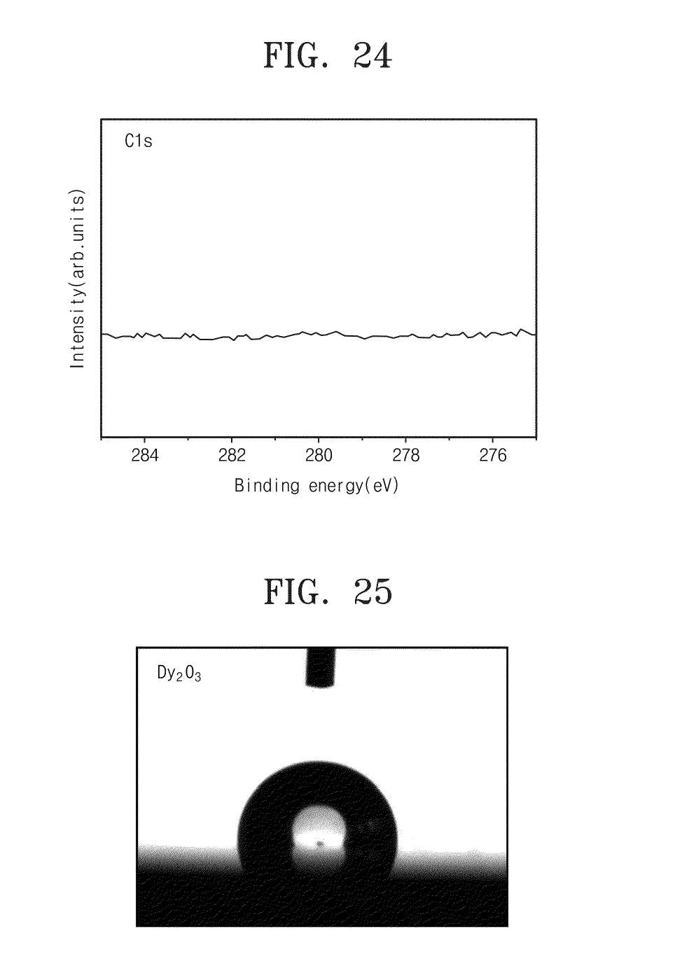

FIG. 21 is a graph obtained by measuring Dy 4d binding energy of a dysprosium oxide coating layer formed on a substrate according to an embodiment of the inventive concept, FIG. 22 is a graph obtained by measuring O 1s binding energy of a dysprosium oxide coating layer formed on a substrate according to an embodiment of the inventive concept, FIG. 23 is a graph obtained by measuring N 1s binding energy of a dysprosium oxide coating layer formed on a substrate according to an embodiment of the inventive concept, and FIG. 24 is a graph obtained by measuring C 1s binding energy of a dysprosium oxide coating layer formed on a substrate according to an embodiment of the inventive concept.

Referring to FIGS. 21 to 24, the peaks of N 1s, C 1s binding energy are rarely shown relative to the peaks of Dy 4s, O 1s binding energy. From the results obtained by integrating and analyzing the distribution of the binding energy, the atomic ratio of a carbon element among elements constituting the coating layer was measured to be less than 1%, and the dysprosium oxide coating layer formed on the substrate according to an embodiment of the inventive concept exhibited hydrophobic property.

In order to evaluate the stability at a high temperature of the dysprosium oxide coating layer according to an embodiment of the inventive concept, the dysprosium oxide coating layer formed on the substrate was heat treated at 500° C. for 2 hours, and the contact angle of the coating layer was measured to evaluate the hydrophobic property. FIG. 25 is a photographic image showing a state of a droplet dropped on a dysprosium oxide coating layer formed on a substrate after heat treatment at a high temperature according to an embodiment of the inventive concept. The contact angle of the coating layer after heat treatment was 107°, which was almost the same as the contact angle (108°) of the coating layer before the heat treatment. Thus, the hydrophobic property of the coating layer was secured to be maintained for a long time after the heat treatment at a high temperature.

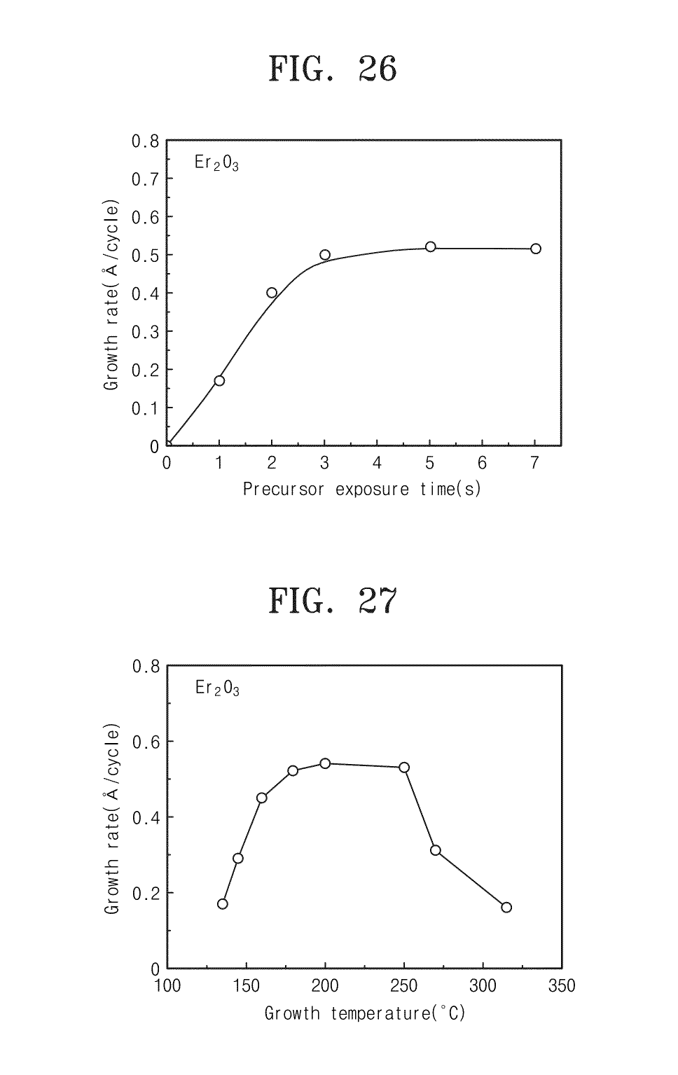

FIG. 26 is a graph showing a growth rate of an erbium oxide coating layer relative to exposure time of a substrate to an erbium precursor. An Si substrate was exposed to an Er(MeCp)₂(N-iPr-amd) precursor, impurities were purged for 5 seconds, the substrate was exposed to an H₂O oxidant for 1 second, and the impurities were purged again for 5 seconds to form an erbium metal oxide coating layer. The temperature of the substrate was maintained to 180° C., and the bubbling temperature of the precursor and the oxidant was set to 110° C.

As shown in FIG. 26, if the exposure time to the precursor is greater than or equal to 3 seconds, the growth rate of the erbium metal oxide coating layer is maintained to an appropriate level (about 0.5 Å/cycle). In order to secure the growth rate of the coating layer to a certain level, while decreasing process time, the exposure time to the erbium precursor may preferably be from 3 to 5 seconds. To maintain the growth rate of the erbium metal oxide coating layer to an appropriate level, the exposure time of an H₂O oxidant may preferably be greater than or equal to 1 second.

FIG. 27 is a graph showing a growth rate of an erbium oxide coating layer relative to the growth temperature (the temperature of a substrate) of a coating layer. The supply time (exposure time) of the precursor was set to 3 seconds, and the exposure time of the oxidant was set to 1 second. Other experimental conditions were the same as those of FIG. 26. As shown in FIG. 27, if the erbium precursor was used, and the temperature of the substrate was in a range of 180 to 250° C., an appropriate growth rate of the coating layer was secured.

In the case of setting the temperature of the substrate to the temperatures (270° C., 320° C.) greater than 250° C., or the temperature (130° C., 150° C., 160° C.) lower than 180° C., the growth rate of the erbium oxide coating layer is decreased. It is supposed that impurities are included in the coating layer instead of the erbium oxide, and the deposition of the erbium oxide is inhibited. That is, if the temperature of the substrate is deviated from an appropriate temperature, the atomic ratio of a carbon element among elements constituting the coating layer is increased to greater than or equal to 1%, and the coating layer thus formed may not have hydrophobic or superhydrophobic property.

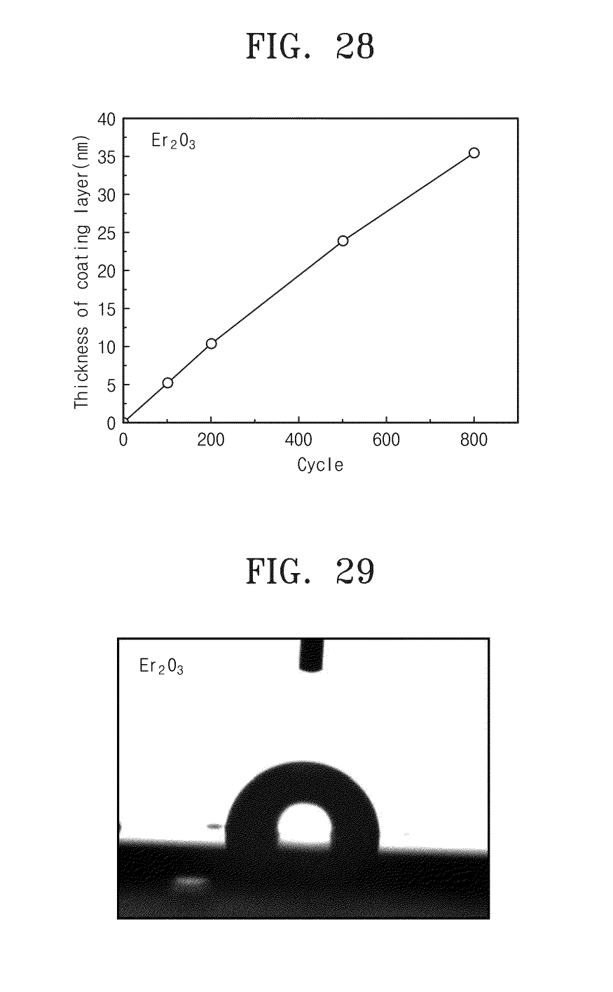

FIG. 28 is a graph showing a thickness of an erbium oxide coating layer relative to cycle number. In this case, the temperature of the substrate was maintained at 180° C., and the exposure time of the precursor was set to 3 seconds. The thickness of the erbium oxide coating layer was measured after performing 100, 200, 500 and 800 cycles, and the other experimental conditions were the same as those of FIG. 26. Referring to FIG. 28, the thickness of the erbium oxide coating layer increases in proportion to the cycle number. Thus, a coating layer with a desired thickness may be formed by controlling the cycle number during the forming process of the coating layer including the steps of S11 to S14 of FIG. 1.

### Example 3

An experiment for securing the formation of a hydrophobic or superhydrophobic coating layer by the method for forming a coating layer according to an embodiment of the inventive concept was conducted. A cycle of exposing an Si substrate in a reaction chamber to an Er(MeCp)₂(N-iPr-amd) precursor for 3 seconds, purging impurities for 5 seconds, exposing the substrate to an H₂O oxidant for 1 second and purging impurities again for 5 seconds, was conducted for several times to form an erbium metal oxide coating layer. The bubbling temperature of the precursor and the oxidant was set to 110° C., and the temperature of the substrate was set to 180° C. The contact angle of the erbium metal oxide coating layer formed according to an embodiment of the inventive concept was measured, and the realization of hydrophobic or superhydrophobic property was judged.

FIG. 29 is a photographic image showing a state of a droplet dropped on an erbium oxide coating layer formed on a substrate according to an embodiment of the inventive concept. The contact angle of the droplet with respect to the erbium oxide coating layer formed according to an embodiment of the inventive concept was 100°, and this result means that the erbium oxide coating layer formed according to an embodiment of the inventive concept has hydrophobic property.

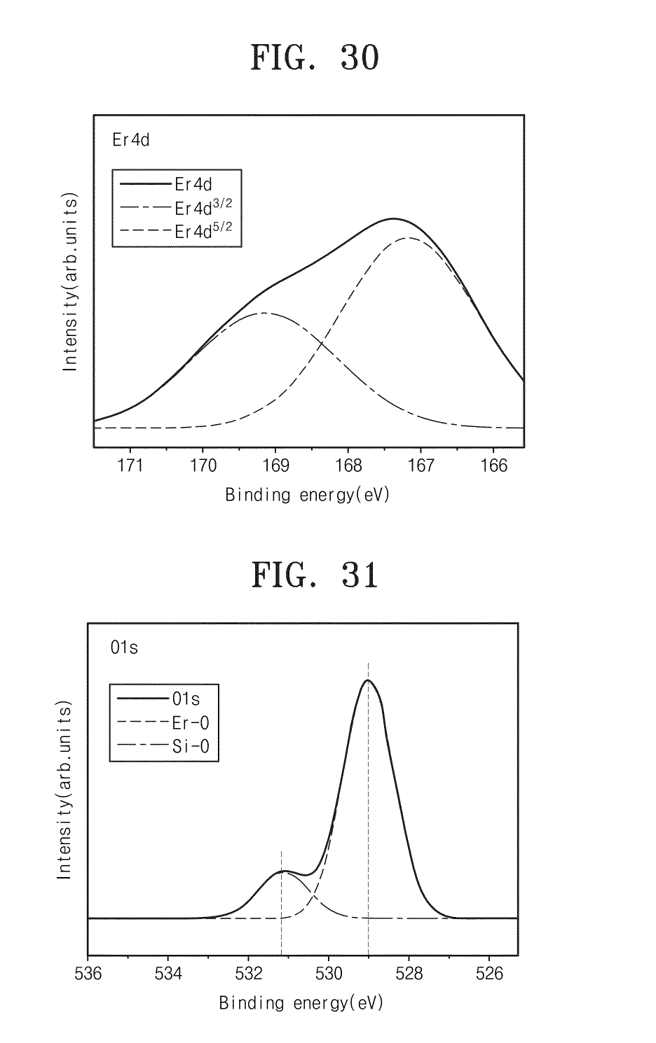

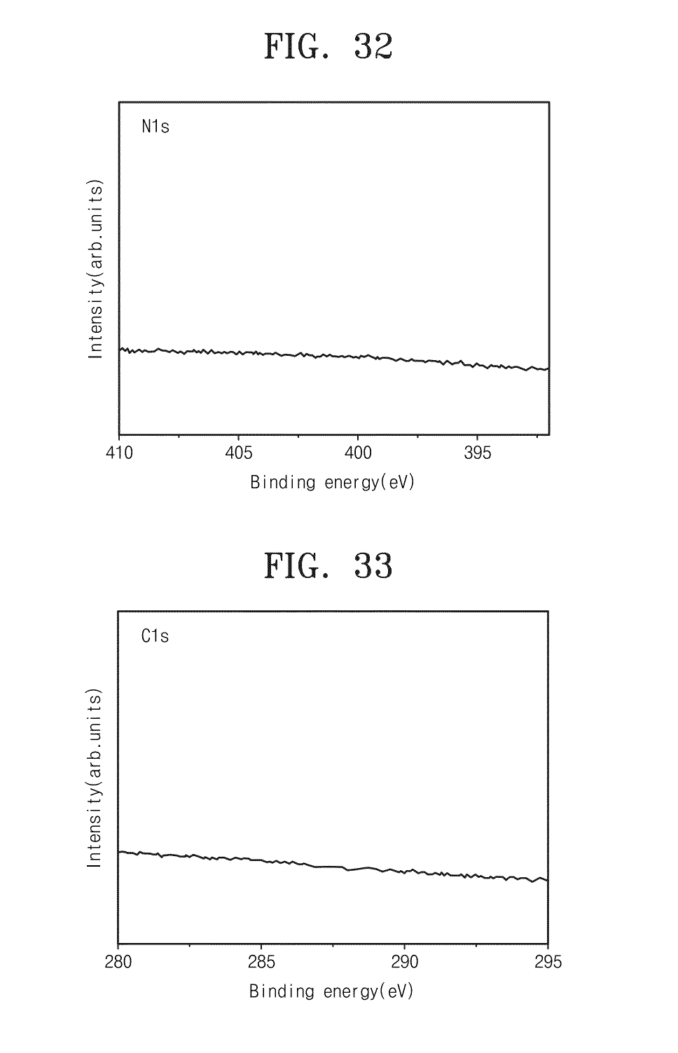

FIG. 30 is a graph obtained by measuring Er 4d binding energy of an erbium oxide coating layer formed on a substrate according to an embodiment of the inventive concept, FIG. 31 is a graph obtained by measuring O 1s binding energy of an erbium oxide coating layer formed on a substrate according to an embodiment of the inventive concept, FIG. 32 is a graph obtained by measuring N 1s binding energy of an erbium oxide coating layer formed on a substrate according to an embodiment of the inventive concept, and FIG. 33 is a graph obtained by measuring C 1s binding energy of an erbium oxide coating layer formed on a substrate according to an embodiment of the inventive concept.

Referring to FIGS. 30 to 33, the peaks of N 1s, C 1s binding energy are rarely shown relative to the peaks of Er 4d, O 1s binding energy. From the results obtained by integrating and analyzing the distribution of the binding energy, the atomic ratio of a carbon element among elements constituting the coating layer was measured to be less than 1%, and the erbium oxide coating layer formed on the substrate according to an embodiment of the inventive concept exhibited hydrophobic property.

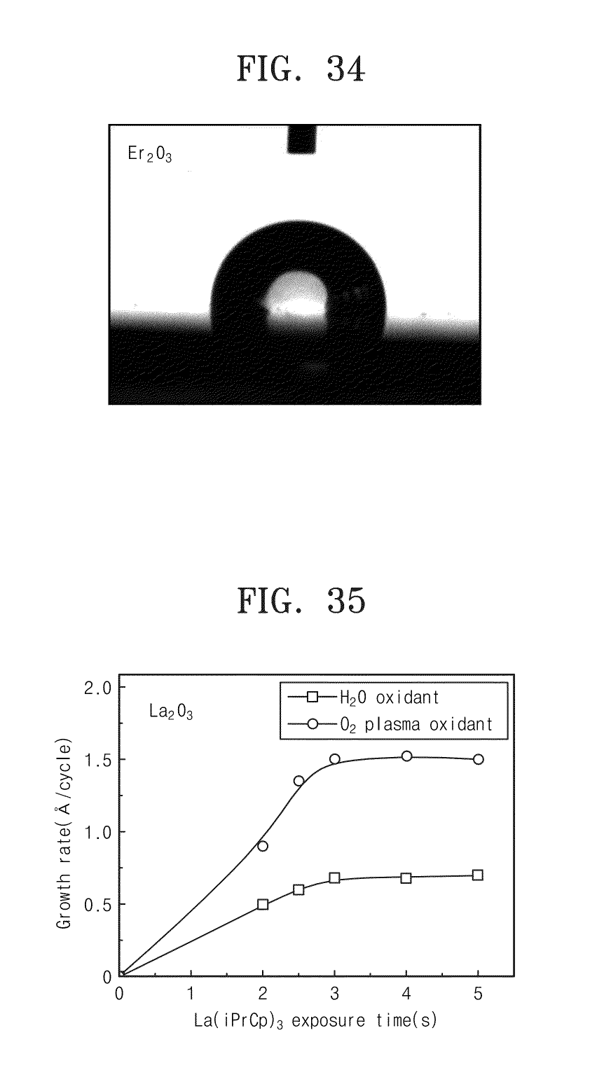

In order to evaluate the stability at a high temperature of the erbium oxide coating layer according to an embodiment of the inventive concept, the erbium oxide coating layer formed on the substrate was heat treated at 500° C. for 2 hours, and the contact angle of the coating layer was measured to evaluate the hydrophobic property. FIG. 34 is a photographic image showing a state of a droplet dropped on an erbium oxide coating layer formed on a substrate after heat treatment at a high temperature according to an embodiment of the inventive concept. The contact angle of the coating layer after heat treatment was 97°, which was maintained to almost the same level as the contact angle (100°) of the coating layer before heat treatment. This result means that hydrophobic property of the coating layer formed according to an embodiment of the inventive concept may be maintained after heat treatment for a long time at a high temperature.

FIG. 35 is a graph showing a growth rate of a lanthanum oxide coating layer relative to exposure time of a substrate to a lanthanum precursor. A Si substrate was exposed to a La(iPrCp)₃ precursor, impurities were purged for 5 seconds, the substrate was exposed to an oxidant for 3 seconds, and the impurities were purged again for 5 seconds to form a lanthanum metal oxide coating layer. The temperature of the substrate was maintained at 300° C. As the oxidant, H₂O and plasma O₂ were used, and the growth rate of the coating layer was measured for each oxidant.

As shown in FIG. 35, if the exposure time to the precursor is greater than or equal to 3 seconds, the growth rate of the lanthanum metal oxide coating layer is maintained to an appropriate level. In order to secure the growth rate of the coating layer to a certain level, while decreasing process time, the exposure time to the erbium precursor may preferably be from 3 to 4 seconds. To maintain the growth rate of the lanthanum metal oxide coating layer to an appropriate level, the exposure time of an oxidant may preferably be greater than or equal to 3 seconds.

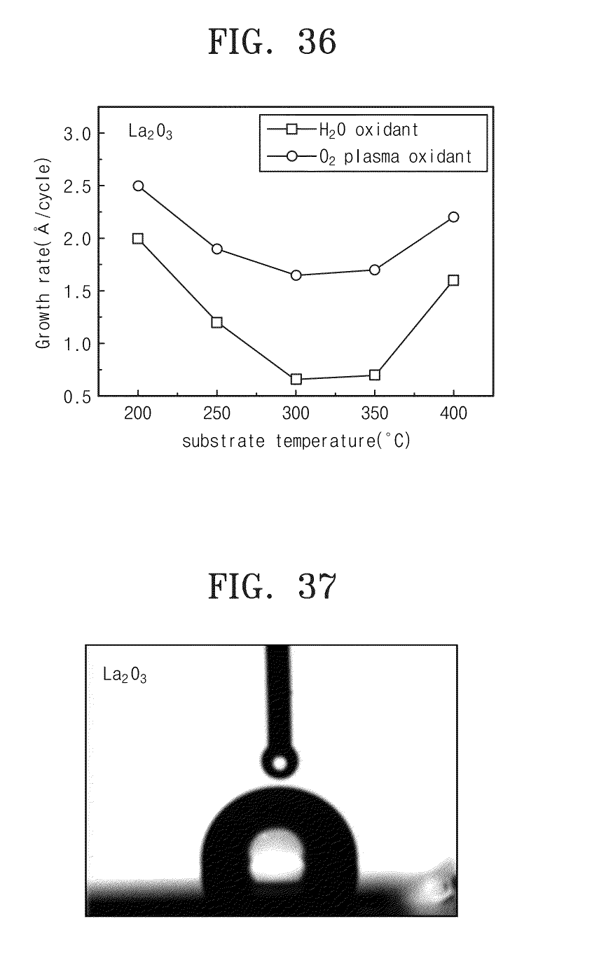

FIG. 36 is a graph showing a growth rate of a lanthanum oxide coating layer relative to the growth temperature (the temperature of a substrate) of a coating layer. The supply times (exposure time) of the precursor and the oxidant were set to 3 seconds, respectively, and other experimental conditions were the same as those of FIG. 35. As shown in FIG. 36, if the lanthanum precursor is used, and the temperature of the substrate is in a range of 250 to 350° C., an appropriate growth rate of the coating layer may be secured.

In the case of setting the temperature of the substrate to the temperature (400° C.) greater than 350° C., or the temperature (200° C.) lower than 250° C., the growth rate of the lanthanum oxide coating layer may be increased. It is supposed that impurities are included other than the lanthanum oxide in the coating layer. That is, if the temperature of the substrate is deviated from an appropriate range, the atomic ratio of a carbon element among elements constituting the coating layer may be increased to greater than or equal to 1%, and the coating layer thus formed may not have hydrophobic or superhydrophobic property.

### Example 4

An experiment for securing the formation of a hydrophobic or superhydrophobic coating layer by the method for forming a coating layer according to an embodiment of the inventive concept was conducted. A cycle of exposing an Si substrate in a reaction chamber to an La(iPrCp)₃ precursor for 3 seconds, purging impurities for 5 seconds, exposing the substrate to an H₂O or plasma O₂ oxidant for 3 seconds and purging impurities again for 5 seconds, was conducted for several times to form a lanthanum metal oxide coating layer. The temperature of the substrate was set to 300° C. The contact angle of the lanthanum metal oxide coating layer formed according to an embodiment of the inventive concept was measured, and the realization of hydrophobic or superhydrophobic property was secured.

FIG. 37 is a photographic image showing a state of a droplet dropped on a lanthanum oxide coating layer formed on a substrate according to an embodiment of the inventive concept. The contact angle of the droplet with respect to the lanthanum oxide coating layer formed according to an embodiment of the inventive concept was 106°, and this result means that the lanthanum oxide coating layer formed according to an embodiment of the inventive concept has hydrophobic property.

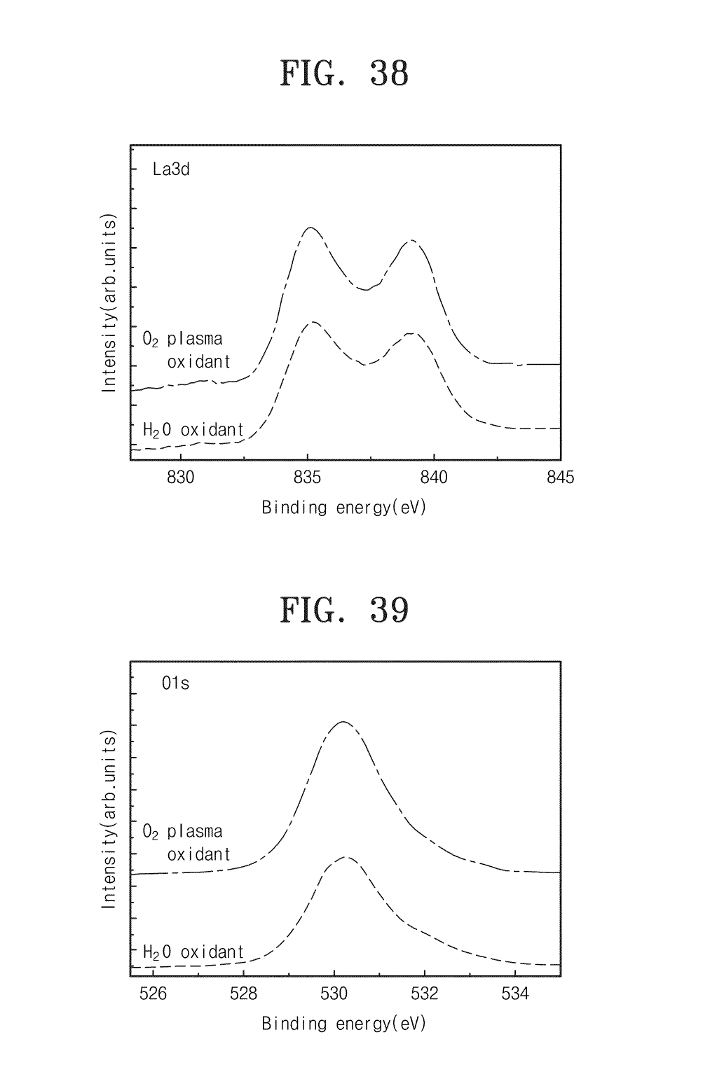

FIG. 38 is a graph obtained by measuring La 3d binding energy of a lanthanum oxide coating layer formed on a substrate according to an embodiment of the inventive concept, and FIG. 39 is a graph obtained by measuring O 1s binding energy of a lanthanum oxide coating layer formed on a substrate according to an embodiment of the inventive concept. By integrating and analyzing the distribution of the binding energy, the atomic ratio of a carbon element among elements constituting the coating layer was measured to less than 1%, and the lanthanum oxide coating layer formed on the substrate according to an embodiment of the inventive concept exhibited hydrophobic property.

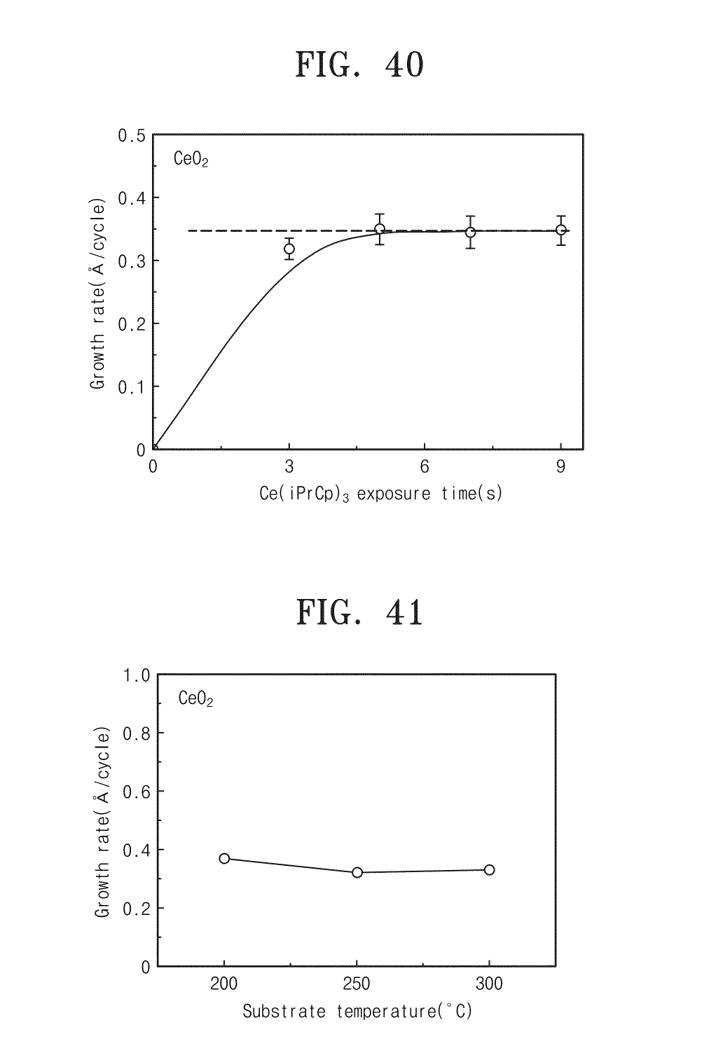

FIG. 40 is a graph showing a growth rate of a cerium oxide coating layer relative to exposure time of a substrate to a cerium precursor. A Si substrate was exposed to a Ce(iPrCp)₃ precursor, impurities were purged for 5 seconds, the substrate was exposed to a plasma O₂ oxidant for 3 second, and the impurities were purged again for 5 seconds to form a cerium metal oxide coating layer. The temperature of the substrate was maintained at 250° C.

As shown in FIG. 40, if the exposure time to the precursor is greater than or equal to 4 seconds, and more preferably, greater than or equal to 5 seconds, the growth rate of the cerium metal oxide coating layer per cycle is maintained to an appropriate level. In order to secure the growth rate of the coating layer to a certain level, while decreasing process time, the exposure time to the cerium precursor may preferably be from 4 to 7 seconds. To maintain the growth rate of the cerium metal oxide coating layer to an appropriate level, the exposure time to the oxidant may preferably be greater than or equal to 3 seconds.

FIG. 41 is a graph showing a growth rate of a cerium oxide coating layer relative to the growth temperature (the temperature of a substrate) of a coating layer. The supply times (exposure time) of the precursor and the oxidant were set to 4 seconds and 3 seconds, respectively, and other experimental conditions were the same as those of FIG. 40. As shown in FIG. 41, if the cerium precursor was used, and the temperature of the substrate was in a range of 200 to 300° C., an appropriate growth rate of the coating layer was secured. If the temperature of the substrate is deviated from an appropriate temperature, impurities other than the cerium oxide may be included in the coating layer, and the atomic ratio of a carbon element among elements constituting the coating layer may be increased to greater than or equal to 1%, and the coating layer having hydrophobic or superhydrophobic property may not be formed.

### Example 5

An experiment for securing the formation of a hydrophobic or superhydrophobic coating layer by the method for forming a coating layer according to an embodiment of the inventive concept was conducted. A cycle of exposing an Si substrate in a reaction chamber to a Ce(iPrCp)₃ precursor for 4 seconds, purging impurities for 5 seconds, exposing the substrate to a plasma O₂ oxidant for 3 seconds and purging impurities again for 5 seconds, was conducted for several times to form a cerium metal oxide coating layer. The temperature of the substrate was set to 250° C. The contact angle of the cerium metal oxide coating layer formed according to an embodiment of the inventive concept was measured, and the realization of hydrophobic or superhydrophobic property was judged.

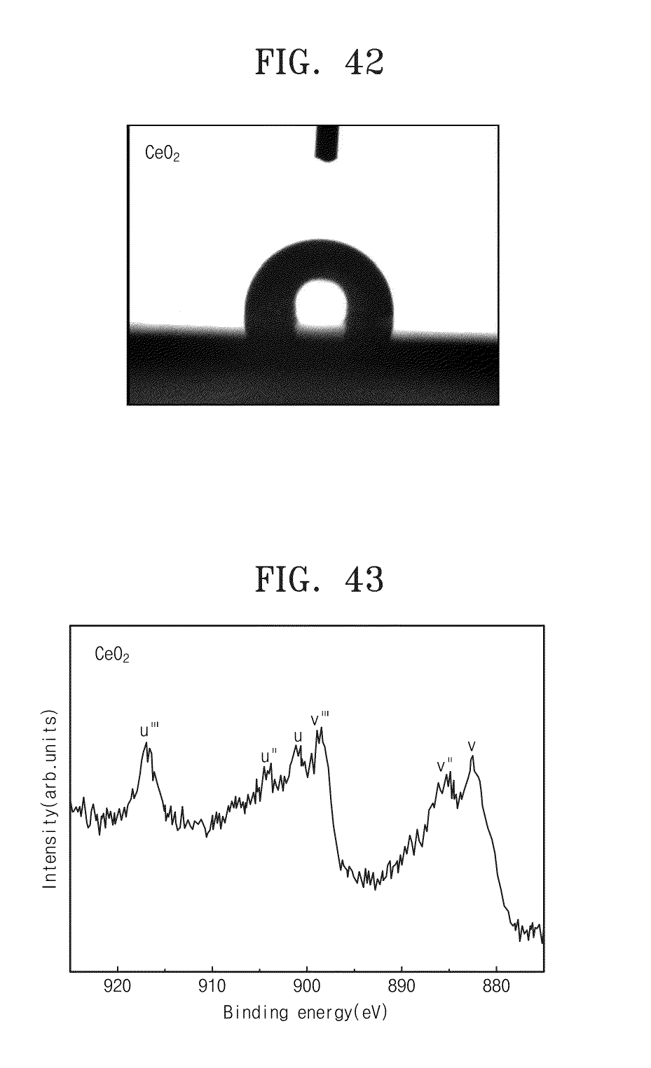

FIG. 42 is a photographic image showing a state of a droplet dropped on a cerium oxide coating layer formed on a substrate according to an embodiment of the inventive concept. The contact angle of the droplet with respect to the cerium oxide coating layer formed according to an embodiment of the inventive concept was 97°, and the result means that the cerium oxide coating layer formed according to an embodiment of the inventive concept has hydrophobic property.

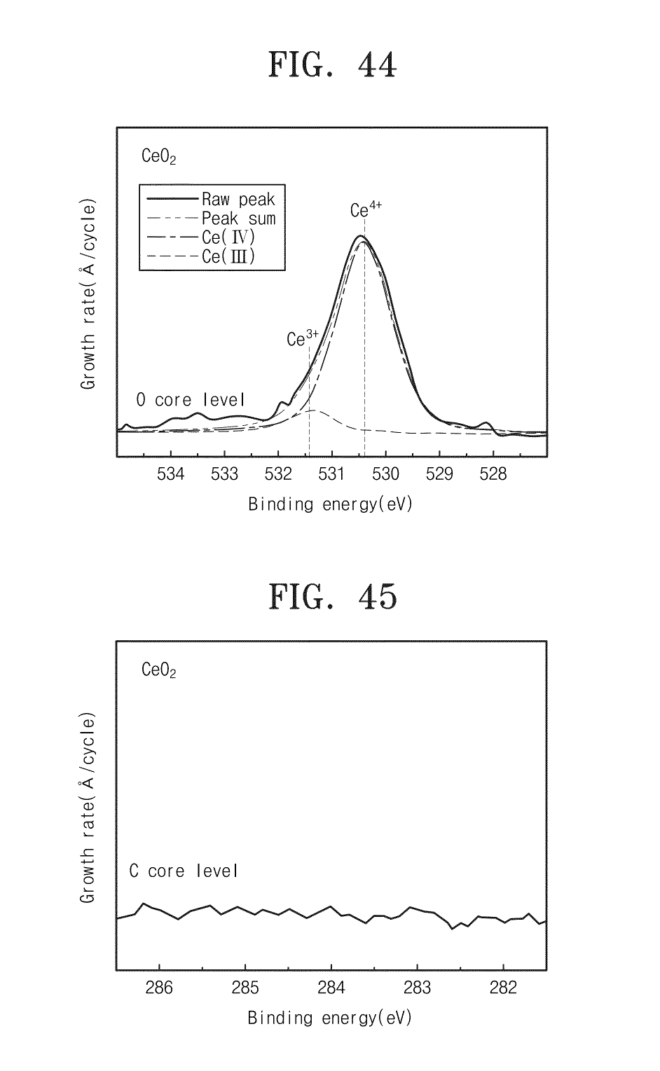

FIG. 43 is a graph obtained by measuring Ce 3d binding energy of a cerium oxide coating layer formed on a substrate according to an embodiment of the inventive concept, FIG. 44 is a graph obtained by measuring O 1s binding energy of a cerium oxide coating layer formed on a substrate according to an embodiment of the inventive concept, and FIG. 45 is a graph obtained by measuring C 1s binding energy of a cerium oxide coating layer formed on a substrate according to an embodiment of the inventive concept.

Referring to FIGS. 43 to 45, the peaks of C 1s binding energy are rarely shown relative to the peaks of Ce 3d, O 1s binding energy. From the results obtained by integrating and analyzing the distribution of the binding energy, the atomic ratio of a carbon element among elements constituting the coating layer was measured to be less than 1%, and the cerium oxide coating layer formed on the substrate according to an embodiment of the inventive concept exhibited hydrophobic property.

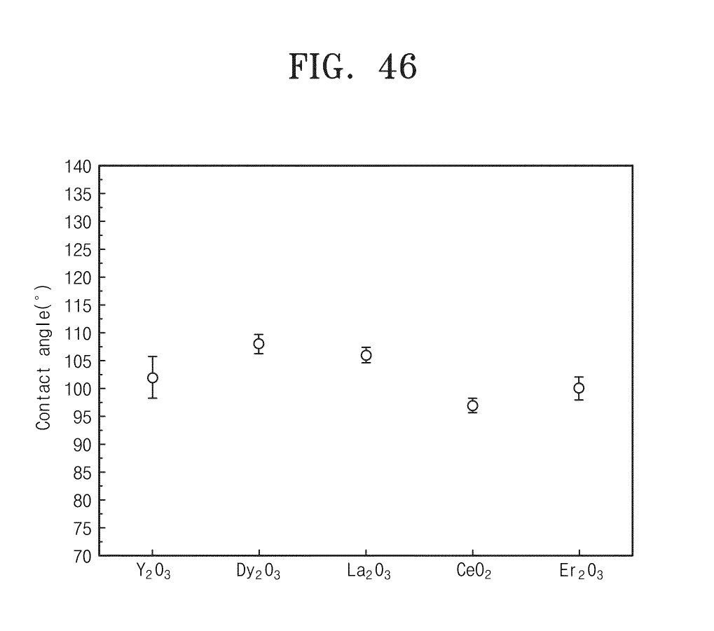

FIG. 46 is a graph showing a contact angle of a coating layer formed on a substrate according to an embodiment of the inventive concept according to the kind of a rare earth oxide. As shown in FIG. 46, the contact angle of the coating layer formed on the substrate according to an embodiment of the inventive concept was from 97 to 108°, and the coating layer was secured to have hydrophobic property.

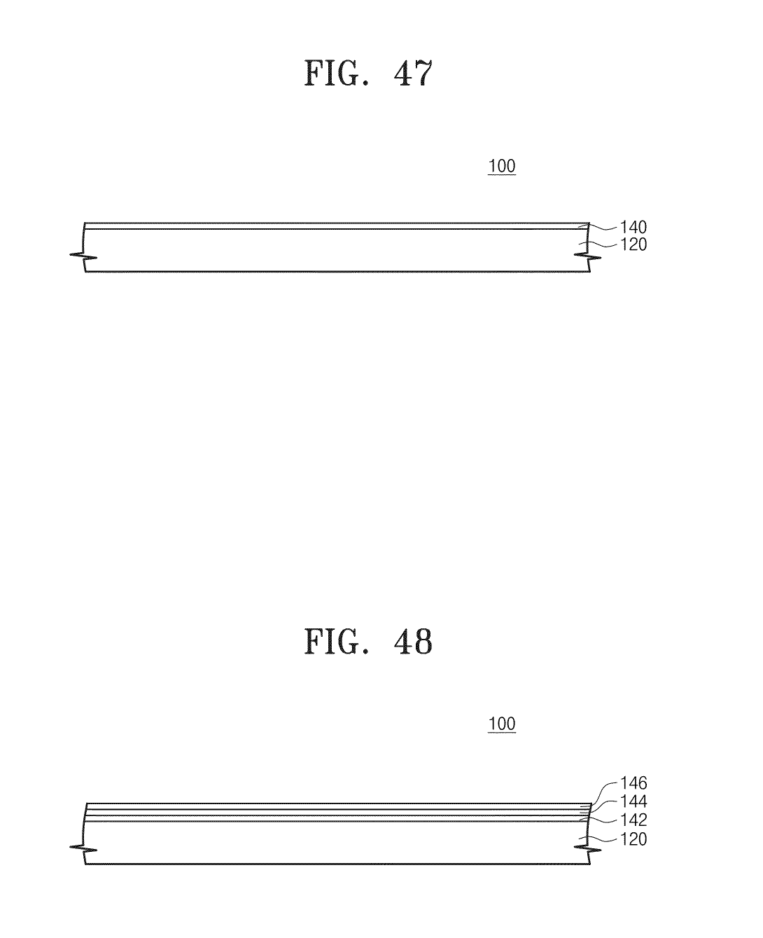

FIG. 47 is a cross-sectional view schematically showing a coating material having waterproof property according to an embodiment of the inventive concept. Referring to FIG. 47, a coating material (100) having waterproof property according to an embodiment of the inventive concept includes a substrate (120) and a coating layer (140) formed on the substrate (120) by the atomic layer unit and including a rare earth metal oxide. The substrate (120) may be, for example, a silicon substrate, a germanium substrate, a multi-element substrate of GaAs, AlGaAs, or InAlGaAs, or a glass substrate, without limitation. For example, the substrate (120) may be a bulk substrate or a silicon on insulator (SOI) substrate in which n-type or p-type impurities are entirely or partially doped.

The coating layer (140) may include, for example, at least one rare earth metal oxide of Y₂O₃, Dy₂O₃, La₂O₃, CeO₂ or Er₂O₃. The coating layer (140) may be formed on the substrate by the above-described method for forming a coating layer. The coating layer (140) may be transparent and may have a contact angle with respect to water greater than 90°, because the atomic ratio of a carbon element among elements forming the coating layer (140) is less than 1%. The coating layer (140) may be a single atomic layer or may be formed as two or more layers. Different from FIG. 47, another layer (not shown) may be further formed between the substrate (120) and the coating layer (140). The substrate (120) may be a substrate having a three-dimensional nano structure formed thereon. The nano structure may include, for example, a nano wire structure. By forming the rare earth metal oxide on the substrate provided with the three-dimensional nano structure by the atomic layer deposition method according to an embodiment of the inventive concept, superhydrophobic property may be realized.

FIG. 48 is a cross-sectional view schematically showing a coating material having waterproof property according to an embodiment of the inventive concept. Referring to FIG. 48, a plurality of coating layers (142, 144, 146) may be formed on the substrate (120). The plurality of the coating layers (142, 144, 146) may be formed using the same oxide of a rare earth element, or oxides of different kinds of rare earth elements. The uppermost coating layer (146) may be formed as a rare earth metal oxide layer having hydrophobic or superhydrophobic property. The coating layers (142, 144) between the uppermost coating layer (146) and the substrate (120) may be coating layers not including the rare earth metal oxide.

The waterproof coating material formed according to an embodiment of the inventive concept has hydrophobic or superhydrophobic property. The waterproof coating material formed according to an embodiment of the inventive concept has thermal stability at a high temperature, and maintains the hydrophobic or superhydrophobic property even after heat treatment at 500° C. for 2 hours. According to an embodiment of the inventive concept, hydrophobic coating with transparency, friction durability, abrasion-resistance, and stability at a high temperature may be manufactured, and through the realization of superhydrophobic surface via coating on a complicated three-dimensional structure, the coating material may be applied to various fields such as a solar cell, automobile parts, cuisine products, etc.

The waterproof coating material according to an embodiment of the inventive concept may be applied to various products including, for example, a transparent or non-reflective coating material, a coating material for limiting humidity of an electronic device, a fiber material not getting wet in water, a separating membrane of water and oil, a superhydrophobic valve, an anticorrosive coating agent of a metal surface by water, a battery, an application material of a fossil fuel, kitchen utensils with antibacterial property, a coating agent of a surgical equipment, glass for automobiles, etc.

The above-disclosed example embodiments are suggested to assist the understanding of the inventive concept and are not restrict the scope of the inventive concept, however various modifiable embodiments fall within the scope of the inventive concept. The technical scope for protection of the inventive concept is to be determined by the technical spirit of claims, and the technical scope for protection of the inventive concept is not limited to the literal description of claims, however the technical values thereof is to be broadened substantially to the invention within equivalent scope.

### EXPLANATION OF DESIGNATED NUMERALS

100: Coating material having waterproof property
120: Substrate
140, 142, 144, 146: Coating layers

1. A method for forming a coating layer, comprising:
(a) supplying a precursor comprising a rare earth metal onto a substrate;
(b) purging impurities of remaining precursor after combination of the rare earth metal onto the substrate;
(c) supplying an oxidant onto the substrate; and
(d) purging remaining impurities after forming a coating layer including a rare earth oxide on the substrate,
wherein a temperature of the substrate is controlled so that an atomic ratio of a carbon element in the coating layer is less than 1% to form the coating layer with hydrophobic or superhydrophobic property.

2. The method for forming a coating layer of claim 1,
wherein the rare earth metal comprises yttrium, and
the rare earth metal oxide comprises yttrium oxide (Y₂O₃).

3. The method for forming a coating layer of claim 2,
wherein the temperature of the substrate is controlled to from 160 to 200° C. so that the atomic ratio of a carbon element in the coating layer is less than 1% to form the coating layer with hydrophobic or superhydrophobic property.

4. The method for forming a coating layer of claim 3,
wherein the precursor comprises Y(iPr(Cp)₂(N-iPr-amd),
the supplying of the precursor in the step of (a) is conducted so that exposure time of the substrate to the precursor is greater than or equal to 1.5 seconds,
the supplying of the oxidant in the step of (c) is conducted so that exposure time of the substrate to the oxidant is greater than or equal to 0.5 seconds, and
the oxidant comprises H₂O.

5. The method for forming a coating layer of claim 1,
wherein the rare earth metal comprises dysprosium, and
the rare earth metal oxide comprises dysprosium oxide (Dy₂O₃).

6. The method for forming a coating layer of claim 5,
wherein the temperature of the substrate is controlled to from 145 to 230° C. so that the atomic ratio of a carbon element in the coating layer is less than 1% to form the coating layer with hydrophobic or superhydrophobic property.

7. The method for forming a coating layer of claim 6,
wherein the precursor comprises Dy(iPrCp)₂(N-iPr-amd),
the supplying of the precursor in the step of (a) is conducted so that exposure time of the substrate to the precursor is greater than or equal to 2 seconds,
the supplying of the oxidant in the step of (c) is conducted so that exposure time of the substrate to the oxidant is greater than or equal to 0.5 seconds, and
the oxidant comprises plasma O₂.

8. The method for forming a coating layer of claim 1,
wherein the rare earth metal comprises erbium, and
the rare earth metal oxide comprises erbium oxide (Er₂O₃).

9. The method for forming a coating layer of claim 8,
wherein the temperature of the substrate is controlled to from 180 to 250° C. so that the atomic ratio of a carbon element in the coating layer is less than 1% to form the coating layer with hydrophobic or superhydrophobic property.

10. The method for forming a coating layer of claim 9,
wherein the precursor comprises Er(MeCp)₂(N-iPr-amd),
the supplying of the precursor in the step of (a) is conducted so that exposure time of the substrate to the precursor is greater than or equal to 3 seconds,
the supplying of the oxidant in the step of (c) is conducted so that exposure time of the substrate to the oxidant is greater than or equal to 1 second, and
the oxidant comprises H₂O.

11. The method for forming a coating layer of claim 1,
wherein the rare earth metal comprises lanthanum, and
the rare earth metal oxide comprises lanthanum oxide (La₂O₃).

12. The method for forming a coating layer of claim 11,
wherein the temperature of the substrate is controlled to from 250 to 350° C. so that the atomic ratio of a carbon element in the coating layer is less than 1% to form the coating layer with hydrophobic or superhydrophobic property.

13. The method for forming a coating layer of claim 12,
wherein the precursor comprises La(iPrCp)₃,
the supplying of the precursor in the step of (a) is conducted so that exposure time of the substrate to the precursor is greater than or equal to 3 seconds,
the supplying of the oxidant in the step of (c) is conducted so that exposure time of the substrate to the oxidant is greater than or equal to 3 seconds, and
the oxidant comprises at least one selected from H₂O and plasma O₂.

14. The method for forming a coating layer of claim 1,
wherein the rare earth metal comprises cerium, and
the rare earth metal oxide comprises cerium oxide (CeO₂).

15. The method for forming a coating layer of claim 14,
wherein the temperature of the substrate is controlled to from 200 to 300° C. so that the atomic ratio of a carbon element in the coating layer is less than 1% to form the coating layer with hydrophobic or superhydrophobic property.

16. The method for forming a coating layer of claim 15,
wherein the precursor comprises Ce(iPrCp)₃,
the supplying of the precursor in the step of (a) is conducted so that exposure time of the substrate to the precursor is greater than or equal to 4 seconds,
the supplying of the oxidant in the step of (c) is conducted so that exposure time of the substrate to the oxidant is greater than or equal to 3 seconds, and
the oxidant comprises plasma O₂.

17. The method for forming a coating layer of claim 1,
wherein the steps of (a) to (d) are repeated to form the coating layer with hydrophobic or superhydrophobic property.

18. A coating material having waterproof property, comprising:
a substrate; and
a coating layer on the substrate by an atomic layer unit, the coating layer comprising a rare earth metal oxide,
wherein the coating layer has less than 1% of an atomic ratio of a carbon element to have hydrophobic or superhydrophobic property.

19. The coating material having waterproof property of claim 18,
wherein a contact angle of the coating layer with water is greater than 90°.

20. The coating material having waterproof property of claim 18,
wherein the hydrophobic or superhydrophobic property of the coating layer is maintained after heat treatment at 500° C. for 2 hours.
